(19) United States
(12) Patent Application Publication
(10) Pub. No.: US 2026/0327479 A1
(43) Pub. Date: Oct. 22, 2026

(54) QUANTUM DOT COMPOSITION, DISPLAY DEVICE AND PATTERNING METHOD OF QUANTUM DOT FILM

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Shaoyong LU, Beijing (CN); Yichi ZHANG, Beijing (CN)

(21) Appl. No.: 18/996,597

(22) PCT Filed: Nov. 28, 2023
(86) PCT No.: PCT/CN2023/134582

§ 371 Date: Jan. 17, 2025

(51) Int. Cl. C09K 11/02; H10K 50/115; H10K 71/20

(52) U.S. Cl. CPC C09K 11/025; H10K 50/115; H10K 71/211

(57) ABSTRACT

At least one embodiment of the present disclosure provides a quantum dot composition, a patterning method of a quantum dot film and a quantum dot display device, the quantum dot composition includes: a quantum dot material and a photosensitizer which are mixed, in which the quantum dot material includes a quantum dot body and a first quantum dot ligand on a surface of the quantum dot body; the photosensitizer is configured to react with the first quantum dot ligand under illumination to form a second quantum dot ligand, a molecular weight of the second quantum dot ligand is greater than a molecular weight of the first quantum dot ligand, and a polarity of the second quantum dot ligand is different from a polarity of the first quantum dot ligand.

### TECHNICAL FIELD

Embodiments of the present disclosure relates to a quantum dot composition, a patterning method of a quantum dot film and a quantum dot display device.

### BACKGROUND

With the continuous development and progress of display technology, it is very important that display devices can present natural colors to the greatest extent and bring viewers a more realistic and shocking visual experience. In the realization of wide color gamut, an optional way is to use quantum dots (QD) to emit light. Quantum dot technology uses nano-scale semiconductor particles to emit light with a specific frequency by applying a certain electric field or light pressure to them, that is, in the display field, quantum dots emit light in two ways: photoluminescence and electroluminescence. The spectrum emitted by the quantum dots is narrower than the half-peak width of the self-luminous spectrum of organic light emitting diodes, and the emitted light is purer in color and higher in color saturation.

A concrete way to realize photoluminescence quantum dots is quantum dots-color film (QD-CF for short). QD-CF can be combined with various blue light backlights such as liquid crystal display (LCD), organic light emitting diode (OLED) and micro light emitting diode (micro LED). Based on the characteristics of short wavelength (430 nm-470 nm) and high energy of blue light, blue light can excite quantum dots to emit light with long wavelength, so that blue light can pass through a color filter composed of red quantum dots and green quantum dots respectively, and the red quantum dots and the green quantum dots in the color filter are excited to emit red light and green light respectively, thus realizing full-color display.

### SUMMARY

The embodiments of the present disclosure relate to a quantum dot composition, a patterning method of a quantum dot film and a quantum dot display device. The quantum dot composition includes a quantum dot material and a photosensitizer which are mixed, the quantum dot material includes a quantum dot body and a first quantum dot ligand on a surface of the quantum dot body; the photosensitizer is configured to react with the first quantum dot ligand under illumination to form a second quantum dot ligand, a molecular weight of the second quantum dot ligand is greater than a molecular weight of the first quantum dot ligand, and a polarity of the second quantum dot ligand is different from a polarity of the first quantum dot ligand. The embodiment of the present disclosure utilizes the original ligand of the quantum dot body without ligand exchange, thus reducing the processing steps and preserving the original properties of the quantum dot as much as possible. There is no need for photoresist process, the principle of the technical solution is simple, and the quantum dot composition is only composed of quantum dots and photosensitizers, so the method has universality. The photosensitizer can pattern the quantum dot composition comprising the quantum dot and the ligand with different component structures; and the quantum dot composition can be designed as a positive lithography composition according to the change of polarity, that is, the quantum dot material in the illumination region is developed and removed; the quantum dot composition can also be designed as a negative lithography composition, that is, the quantum dot material in the non-illumination region is developed and removed.

At least one embodiment of the present disclosure provides a quantum dot composition, and the quantum dot composition includes: a quantum dot material and a photosensitizer which are mixed, the quantum dot material comprises a quantum dot body and a first quantum dot ligand on a surface of the quantum dot body; the photosensitizer is configured to react with the first quantum dot ligand under illumination to form a second quantum dot ligand, a molecular weight of the second quantum dot ligand is greater than a molecular weight of the first quantum dot ligand, and a polarity of the second quantum dot ligand is different from a polarity of the first quantum dot ligand.

For example, in the quantum dot composition provided by at least one embodiment of the present disclosure, a polarity index of the second quantum dot ligand is greater than or equal to 0 and less than 3.6, and correspondingly, a polarity index of the first quantum dot ligand is greater than 3.6 and less than 13; or, the polarity index of the first quantum dot ligand is greater than or equal to 0 and less than 3.6, and correspondingly, the polarity index of the second quantum dot ligand is greater than 3.6 and less than 13.

For example, in the quantum dot composition provided by at least one embodiment of the present disclosure, the first quantum dot ligand comprises a coordination group combined with the surface of the quantum dot body, a first connection group connected with the coordination group, and a first functional group connected with the first connection group; the photosensitizer comprises a photosensitive group, a second connection group connected with the photosensitive group, and a second functional group connected with the second connection group; the first functional group and the second functional group have different polarities.

For example, in the quantum dot composition provided by at least one embodiment of the present disclosure, the first quantum dot ligand comprises a C—H bond, and the photosensitive group is configured to undergo a hydrocarbon insertion reaction with the C—H bond comprised in the first quantum dot ligand under illumination to form the second quantum dot ligand.

For example, in the quantum dot composition provided by at least one embodiment of the present disclosure, the photosensitive group forms at least one selected from the group consisting of nitrogen carbene, carbonyl radical and carbene under illumination, and at least one of the nitrogen carbene, the carbonyl radical and the carbene undergoes a hydrocarbon insertion reaction with the C—H bond comprised in the first quantum dot ligand to form the second quantum dot ligand.

For example, in the quantum dot composition provided by at least one embodiment of the present disclosure, the photosensitive group comprises at least one selected from the group consisting of azide, benzophenone and diazirine.

For example, in the quantum dot composition provided by at least one embodiment of the present disclosure, the quantum dot ligand comprises a C═C bond, and the photosensitive group is configured to undergo an addition reaction with the C═C bond comprised in the first quantum dot ligand under illumination to form the second quantum dot ligand.

For example, in the quantum dot composition provided by at least one embodiment of the present disclosure, the photosensitive group forms a nitrogen carbene under illumination, and the nitrogen carbene undergoes an addition reaction with the C═C bond comprised in the first quantum dot ligand to form the second quantum dot ligand.

For example, in the quantum dot composition provided by at least one embodiment of the present disclosure, the photosensitive group comprises azide.

For example, in the quantum dot composition provided by at least one embodiment of the present disclosure, the coordination group comprises at least one selected from the group consisting of sulfhydryl, carboxyl, amino, phosphine and phosphine oxide; the first connection group comprises at least one selected from the group consisting of C1-C30 linear alkyl, unsaturated hydrocarbon chain with one or more double bonds or benzene rings, and polyether segment compound; the first functional group comprises at least one selected from the group consisting of methyl, phenyl, sulfonic acid, carboxyl, nitroso, cyano, hydroxyl, amide, phenolic hydroxyl, sulfhydryl, amino, aldehyde, carbonyl, alkenyl, alkynyl, ether bond and thioether bond.

For example, in the quantum dot composition provided by at least one embodiment of the present disclosure, the second connection group comprises C1-C30 linear alkyl and unsaturated hydrocarbon chain with one or more double bonds or benzene rings; the second functional group comprises at least one selected from the group consisting of sulfonic acid, carboxyl, nitroso, cyano, hydroxyl, amide, phenolic hydroxyl, sulfhydryl, amino, methyl, aldehyde, alkyl, carbonyl, alkenyl, alkynyl, ether bond and thioether bond.

For example, in the quantum dot composition provided by at least one embodiment of the present disclosure, the second functional group is at least one selected from the group consisting of sulfonic acid, carboxyl, nitroso, cyano, hydroxyl, amide, phenolic hydroxyl, sulfhydryl and amino, and the first functional group is at least one selected from the group consisting of methyl, aldehyde, carbonyl, alkenyl, alkynyl, ether bond and thioether bond; or the second functional group is at least one selected from the group consisting of methyl, aldehyde, alkyl, carbonyl, alkenyl, alkynyl, ether bond and thioether bond, and the first functional group is at least one selected from the group consisting of phenyl, sulfonic acid, carboxyl, nitroso, cyano, hydroxyl, amide, phenolic hydroxyl, sulfhydryl and amino.

For example, the quantum dot composition provided by at least one embodiment of the present disclosure, further includes a solvent, and the solvent is a weakly polar solvent or a nonpolar solvent, the first functional group is a weakly polar group or a nonpolar group, and the second functional group corresponding to the first functional group is a strongly polar group, and a dielectric constant of the weakly polar solvent or the nonpolar solvent is less than 3.6.

For example, in the quantum dot composition provided by at least one embodiment of the present disclosure, the first quantum dot ligand is 1-octanethiol or oleic acid, the photosensitizer is 2,3,4,5-tetrafluoro-4-azidebenzoic acid or 3-benzoyl benzoic acid, and the solvent is the weakly polar solvent or nonpolar solvent.

For example, in the quantum dot composition provided by at least one embodiment of the present disclosure, the weakly polar solvent or nonpolar solvent comprises at least one selected from the group consisting of cyclohexane, petroleum ether, octane, trimethylpentane, carbon tetrachloride, trichlorotrifluoroethane, p-xylene, chlorobenzene, o-dichlorobenzene, diethyl ether, diethoxyethane, tetrahydrofuran, hexane, pentane, toluene and chlorobenzene.

For example, the quantum dot composition provided by at least one embodiment of the present disclosure, further includes a solvent, in which the solvent is a strongly polar solvent, the first functional group is a strongly polar group, and the second functional group corresponding to the first functional group is a weakly polar group or a nonpolar group, and a dielectric constant of the strongly polar solvent is greater than or equal to 3.6.

For example, the quantum dot composition provided by at least one embodiment of the present disclosure, further includes the first quantum dot ligand is 6-mercaptohexanol, the photosensitizer is 2,3,4,5-tetrafluoro-4-azido octadecyl benzene, and the solvent is the strongly polar solvent.

For example, the quantum dot composition provided by at least one embodiment of the present disclosure, further includes the strongly polar solvent comprises at least one selected from the group consisting of methanol, ethanol, isopropanol, ethyl acetate, acetonitrile, acetone, acetic acid, pyridine, N,N-dimethylformamide and dimethyl sulfoxide.

At least one embodiment of the present disclosure further provides a patterning method of a quantum dot film, which includes: providing a substrate; applying the quantum dot composition according to any one of the above embodiments on the substrate to form a quantum dot film; shielding the quantum dot film with a mask plate, and irradiating a partial region of the quantum dot film with light to increase a molecular weight of the quantum dot ligand and change a polarity of the quantum dot ligand in the partial regio developing the quantum dot film with a developer to obtain a patterned quantum dot film.

For example, in the patterning method of the quantum dot film provided by at least one embodiment of the present disclosure, irradiating the partial region of the quantum dot film with light to increase the molecular weight of the quantum dot ligand and change the polarity of the quantum dot ligand in the partial region comprises: using the mask plate to shield the quantum dot film, and irradiating the partial region of the quantum dot film with ultraviolet light or infrared light to increase the molecular weight of the quantum dot ligand in the partial region irradiated by the ultraviolet light or the infrared light to form the second quantum dot ligand.

For example, in the patterning method of the quantum dot film provided by at least one embodiment of the present disclosure, developing the quantum dot film with the developer to obtain the patterned quantum dot film comprises: removing the quantum dot film in a region except an illumination region by adopting a negative developer to obtain the patterned quantum dot film; or removing the quantum dot film in the illumination region by adopting a positive developer to obtain the patterned quantum dot film.

For example, in the patterning method of the quantum dot film provided by at least one embodiment of the present disclosure, the polarity of the quantum dot ligand is less than the polarity of the photosensitizer, and forming the patterned quantum dot film comprises: removing the quantum dot film in the region except the illumination region by adopting a nonpolar negative developer to obtain the patterned quantum dot film; or removing the quantum dot film in the illumination region by adopting a polar positive developer to obtain the patterned quantum dot film.

For example, in the patterning method of the quantum dot film provided by at least one embodiment of the present disclosure, the polarity of the quantum dot ligand is greater than the polarity of the photosensitizer, and forming the patterned quantum dot film comprises: removing the quantum dot film in the region except the illumination region by adopting a polar negative developer to obtain the patterned quantum dot film; or removing the quantum dot film in the illumination region by adopting a nonpolar positive developer to obtain the patterned quantum dot film.

At least one embodiment of the present disclosure further provides a quantum dot display device, which includes a quantum dot film prepared from the quantum dot composition according to any one of the above-mentioned embodiments.

For example, in the quantum dot display device provided by at least one embodiment of the present disclosure, the quantum dot display device is a quantum dot light emitting device, and the quantum dot light emitting device comprises a first electrode, a second electrode and the quantum dot film sandwiched between the first electrode and the second electrode.

For example, in the quantum dot display device provided by at least one embodiment of the present disclosure, the quantum dot display device is a quantum dot color conversion device, and the quantum dot color conversion device comprises a light emitting substrate and the quantum dot film located on the light emitting substrate.

### BRIEF DESCRIPTION OF DRAWINGS

In order to explain the technical solution of the embodiments of the present disclosure more clearly, the attached drawings of the embodiments will be briefly introduced below. Obviously, the attached drawings in the following description only relate to some embodiments of the present disclosure, and are not limited to the present disclosure.

FIG. 1 is a flowchart of a patterning method of a quantum dot film provided by at least one embodiment of the present disclosure;

FIG. 2 is a process diagram of a patterning method of a quantum dot film provided by at least one embodiment of the present disclosure;

FIG. 3 is a fluorescence microscope picture of a quantum dot film formed by a patterning method of a quantum dot film provided in a fourth embodiment of the present disclosure;

FIG. 4 is a fluorescence microscope picture of a quantum dot film formed by the patterning method of a quantum dot film provided by a comparative example of the fourth embodiment;

FIG. 5 is a process diagram of forming a full-color pattern provided by at least one embodiment of the present disclosure;

FIG. 6 is another process diagram of forming another full-color pattern provided by at least one embodiment of the present disclosure;

FIG. 7 is another process diagram of forming still another full-color pattern provided by at least one embodiment of the present disclosure;

FIG. 8 is another process diagram of forming still another full-color pattern provided by at least one embodiment of the present disclosure;

FIG. 9 is a schematic cross-sectional view of a quantum dot display device provided by at least one embodiment of the present disclosure;

FIG. 10 is a schematic cross-sectional view of another quantum dot display device provided by at least one embodiment of the present disclosure; and

FIG. 11 is a schematic cross-sectional view of yet another quantum dot display device provided by at least one embodiment of the present disclosure.

### DETAILED DESCRIPTION

In order to make the purpose, technical solution and advantages of the embodiment of the present disclosure clear, the technical solution of the embodiment of the present disclosure will be described clearly and completely with the accompanying drawings of specific embodiments of the present disclosure. It should be noted that the described embodiment is a portion of the embodiment of the present disclosure, not the whole embodiment. Based on the described embodiments of the present disclosure, all other embodiments obtained by ordinary people in the field without creative labor belong to the scope of protection of the present disclosure.

Unless otherwise defined, technical terms or scientific terms used in the present disclosure shall have their ordinary meanings as understood by people with ordinary skills in the field to which the present disclosure belongs. The terms “first”, “second” and the like used in the present disclosure do not indicate any order, quantity or importance, but are only used to distinguish different components. Similar words such as “including” or “containing” refer to that the elements or objects appearing before the word cover the elements or objects listed after the word and their equivalents, without excluding other elements or objects.

The confinement effect of quantum dot material makes it have the property of energy level regulation according to size and morphology, and the property of broadband absorption and narrowband emission. Quantum dot material usually exists in the form of solution, which can be directly processed, thus avoiding the use of expensive vacuum equipment, making the quantum dot materials have large-scale potential applications in the fields of display, lighting, solar cells and photoelectric detection. Patterning is the only way to realize the pixelization of quantum dot material in solution, and to turn the quantum dot material into molded photoelectric devices and even commercial products. The patterning of quantum dots can be realized by the traditional indirect photoresist method, but because of the incompatibility between quantum dot solvent and photoresist solvent, and the introduction of photoresist usually reduces the luminescent properties of quantum dots themselves, it is difficult to realize the patterning of quantum dots by the traditional photoresist process.

The surface of the quantum dot body usually has ligands, which are photo-responsive, thus endowing the quantum dot material with the function of direct lithography patterning. The main principle of lithography patterning is to use a photosensitive group in a photosensitizer to react with the ligand on the surface of quantum dots to change the chemical characteristics of the surfaces of quantum dots, thus changing the solubility and colloidal stability of the quantum dots. Quantum dot bodies coated with surface ligand molecules with different polarities can be dissolved in solvents with corresponding polarities, but cannot be dissolved in other solvents with too different polarities. Therefore, it is an effective way to realize the patterning of quantum dot film by introducing photochemical reaction design from the perspective of changing molecular polarity. Dimitri et al. have developed a variety of quantum dot inks in which surfaces of the quantum dots are coated with inorganic ligands and easily dissolved in polar solvents. The surface ligand molecules in the quantum dots in the quantum dot inks will undergo decomposition reaction after illumination, so that the quantum dots will no longer dissolve in the original solvent, thus achieving the effect of developing and retaining a film. However, there are usually organic ligands on the surfaces of quantum dots. In order to obtain a quantum dot material coated with inorganic photosensitive ligand, it is needed to carry out ligand exchange process on the quantum dots, which has the risk of weakening the photoelectric properties of quantum dots. Therefore, it is of obvious development significance to use the original ligands on the surface of quantum dot without ligand exchange process and introduce a new photochemical reaction system to change the polarity of the ligands on the surfaces of the quantum dots.

The inventor(s) of the present disclosure has noticed that the effect of photoetching and patterning quantum dots can be realized by using the characteristic that the polarity of ligands on the surfaces of quantum dots changes after illumination, so that the quantum dot material is no longer dissolved in the original good solvent. The photoetching and patterning method includes the following steps: forming a thin film on a main surface of a substrate with a mixed solution of a quantum dot material and a photosensitizer with photo-responsive and a polarity changing group by means of blade coating, spin coating, spraying and the like; under the condition of exposure, using a photo mask plate to undergo a photochemical reaction in an illumination region of the thin film, so that the property of the surface ligands of the quantum dot bodies in the illumination region is different from the property of the surface ligands of the quantum dot bodies in the non-illumination region, which includes the difference of polarity and non-polarity, the difference of strong polarity and weak polarity, and the property difference is enough to cause the solubility of quantum dot material in the illumination region to change in the original good solvent. Finally, the quantum dot material in the illumination region or the region without illumination is removed by elution and development of a solvent with a specific polarity, and accordingly a positively patterned quantum dot film or a negatively patterned quantum dot film is obtained. The process of implementing this method is simple, and the lithography patterning is directly carried out by using the changing characteristics of the surface chemical properties of the quantum dot body, which avoids the damage of the introduction of photoresist to the photoelectric properties of the quantum dots, and the subsequent development mode is flexible. By selecting solvents with different polarities for development, a quantum dot film with a positive pattern or a quantum dot film with a negative pattern can be obtained.

The embodiments of the present disclosure relate to a quantum dot composition, a patterning method of a quantum dot film and a quantum dot display device. The quantum dot composition includes a quantum dot material and a photosensitizer which are mixed, the quantum dot material includes a quantum dot body and a first quantum dot ligand on a surface of the quantum dot body, the photosensitizer is configured to react with the first quantum dot ligand under illumination to form a second quantum dot ligand, and a molecular weight of the second quantum dot ligand is greater than a molecular weight of the first quantum dot ligand, and a polarity of the second quantum dot ligand is different from a polarity of the first quantum dot ligand. The embodiment of the present disclosure uses the property that the polarity of the original ligand of the quantum dot changes after being connected with a specific group in the photosensitizer to achieve the purpose of photoetching and patterning a quantum dot film.

At least one embodiment of the present disclosure provides a quantum dot composition, and the quantum dot composition includes a quantum dot material and a photosensitizer which are mixed, the quantum dot material includes a quantum dot body and a first quantum dot ligand on a surface of the quantum dot body; the photosensitizer is configured to react with the first quantum dot ligand under illumination to form a second quantum dot ligand, a molecular weight of the second quantum dot ligand is greater than a molecular weight of the first quantum dot ligand, and a polarity of the second quantum dot ligand is different from a polarity of the first quantum dot ligand. In the embodiment of the present disclosure, the key to selecting the photosensitizer is that the photosensitizer includes a photosensitive group and a polarity change group. Before illumination, the photosensitizer can form a mixed solution with the quantum dots, after forming a quantum dot film and being subjected to illumination, the photosensitive group in the photosensitizer react with the ligand on the surface of the quantum dot body, so that the polarity change group is grafted on the surface ligand of the quantum dot body to achieve the purpose and effect of changing the polarity of the surface ligand of the quantum dot body.

It should be noted that, the polarity in the “the polarity of the second quantum dot ligand is different from the polarity of the first quantum dot ligand” does not intend to limit that both the second quantum dot ligand and the first quantum dot ligand have polarities, and the polarity here is only used to represent a property of the second quantum dot ligand and the first quantum dot ligand. It is possible that the first quantum dot ligand has no polarity, that is, the first quantum dot ligand is nonpolar and the second quantum dot ligand has strong polarity; it is also possible that the first quantum dot ligand has weak polarity and the second quantum dot ligand has strong polarity; it is also possible that the first quantum dot ligand has strong polarity and the second quantum dot ligand has weak polarity; it is also possible that the first quantum dot ligand has strong polarity and the second quantum dot ligand has no polarity, that is, the second quantum dot ligand is nonpolar, the embodiments of the present disclosure are not limited thereto.

For example, in an example, a polarity index of the second quantum dot ligand is greater than or equal to 0 and less than 3,6, and correspondingly, the polarity index of the first quantum dot ligand is greater than 3.6 and less than 13. Alternatively, in another example, the polarity index of the first quantum dot ligand is greater than or equal to 0 and less than 3.6, and correspondingly the polarity index of the second quantum dot ligand is greater than 3.6 and less than 13. For example, a difference between the polarity index of the second quantum dot ligand and the polarity index of the first quantum dot ligand is at least greater than 3.6.

For example, the quantum dot material and photosensitizer which are mixed can be mixed uniformly or heterogeneously, and the embodiment of the present disclosure does not specifically limit the degree of uniformity of mixing.

For example, different photosensitizers can be added to different quantum dot bodies according to the types of ligands on their surfaces. The ligand on the surface of quantum dot body includes oxygen coordinated ligand, nitrogen coordinated ligand, phosphine coordinated ligand or sulfur coordinated ligand. For example, the oxygen coordinated ligand includes carboxylate, the nitrogen coordinated ligand includes amino, the phosphine coordinated ligand includes phosphine, and the sulfur coordinated ligand includes sulfhydryl. For example, the carboxylate ligand on the surface of quantum dot body includes oleic acid, the amino ligand on the surface of quantum dot body includes oleylamine, the phosphine ligand on the surface of quantum dot body includes trioctylphosphine, and the sulfhydryl ligand on the surface of quantum dot body includes dodecyl mercaptan. The photosensitizer includes a photoacid generator, an alkene material or an alkyne material. In a case that the ligand on the surface of quantum dot body is carboxylate ligand, the corresponding photosensitizer can be diazonaphthoquinones, triazines, trifluorosulfonates and so on. In a case that the ligand on the surface of the quantum dot body is sulfhydryl ligand, the doped photosensitive material can be olefins, alkynes and so on. Of course, the photosensitizer is not limited to photoacid generator, the alkene material or the alkyne material, and the corresponding photosensitizer can be selected according to the type of the ligand on the surface of the quantum dot body.

For example, compared with the conventional quantum dot composition, the quantum dot composition in the embodiment of the present disclosure has the advantages that the original ligand of the quantum dot body is utilized without ligand exchange, so that the processing steps are reduced, and the original properties of the quantum dot are kept as much as possible. There is no need for photoresist process, and the principle of the technical solution is simple, and the quantum dot composition is only composed of quantum dots and photosensitizers, so that the method has universality. Photosensitizers can pattern quantum dots and ligands with different component structures, according to the change of the polarity, the quantum dot composition can be designed into positive lithography composition, that is, the quantum dot material in the illumination region is developed and removed; the quantum dot composition can also be designed as a negative lithography composition, that is, the quantum dot material in the non-illumination region is developed and removed.

For example, a quantum dot layer with different colors formed from different quantum dot compositions include quantum dot bodies that emit light with different colors, the quantum dot bodies that emit light with different colors may be semiconductor nanocrystals and may have various shapes, such as spherical, conical, multi-armed and/or cubic nanoparticles, nanotubes, nanowires, nanofibers, nanoplate particles, quantum rods, or quantum sheets. For example, the quantum rod may be a quantum dot having an aspect ratio (a ratio of length to radial size) (a ratio of length to width) greater than about 1, for example, greater than or equal to about 2, greater than or equal to about 3, or greater than or equal to about 5. For example, the quantum rod may have an aspect ratio of less than or equal to about 50, less than or equal to about 30, or less than or equal to about 20.

For example, in an example, the quantum dot body may have a particle diameter of, for example, about 1 nm to 100 nm, about 1 nm to 80 nm, about 1 nm to 50 nm, or about 1 nm to 20 nm (the particle diameter is an average maximum particle length for non-spherical shapes).

For example, the energy band gap of the quantum dot body can be controlled according to the size and the composition of the quantum dot body, and thus the emission wavelength can be controlled. For example, in a case that the size of the quantum dot body increases, the quantum dot body may have a narrow band gap and may emit light in a relatively long wavelength region, while in a case that the size of the quantum dot body decreases, the quantum dot body may have a wide band gap and thus may emit light in a relatively short wavelength region. For example, the quantum dot body may be configured to emit light in a predetermined wavelength region in the visible region according to its size and/or composition. For example, the quantum dot body may emit blue light, red light or green light, and the blue light may have a peak emission wavelength (λ max) in, for example, about 430 nm to about 480 nm, the red light may have a peak emission wavelength (λ max) in, for example, about 600 nm to about 650 nm, and the green light may have a peak emission wavelength (λ max) in, for example, about 520 nm to about 560 nm.

For example, the average particle size of the quantum dot body that can emit blue light is, for example, less than or equal to about 4.5 nm, such as less than or equal to about 4.3 nm, less than or equal to about 4.2 nm, less than or equal to about 4.1 nm, or less than or equal to about 4.0 nm. Within the above ranges, for example, the average particle size of the quantum dot body may be about 2.0 nm to about 4.5 nm, such as about 2.0 nm to about 4.3 nm, about 2.0 nm to about 4.2 nm, about 2.0 nm to about 4.1 nm, or about 2.0 nm to about 4.0 nm.

For example, the quantum dot body may have a relatively narrow half width (FWHM), FWHM is a width corresponding to half of the wavelength of the peak absorption point, and when the FWHM is narrow, the quantum dot body may be configured to emit light in a narrow wavelength region, and relatively high color purity may be obtained. The quantum dot body may have a FWHM of, for example, less than or equal to about 50 nm. Within the above range, the quantum dot body may have a FWHM of, for example, about 2 nm to about 49 nm.

For example, the material of the quantum dot body may include II-VI group semiconductor compound, III-V group semiconductor compound, IV-VI group semiconductor compound, I-III-VI group semiconductor compound, I-II-IV-VI group semiconductor compound, II-III-V group semiconductor compound, or a combination of the above compounds. The II-VI group semiconductor compound is selected from, for example, binary compounds such as CdS, CdSe, CdTe, ZnS, ZnSe, ZnTe, ZnO, HgS, HgSe, HgTe, MgSe, and MgS, or a mixture of at least two of the above compounds; or, the II-VI group semiconductor compound is selected from ternary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and MgZnS or a mixture of at least two of the above compounds. For example, in another example, the II-VI group semiconductor compound can also be HgₓCd₍₁₋ₓ₎Te, HgₓCd₍₁₋ₓ₎S, HgₓCd₍₁₋ₓ₎Se, HgₓZn₍₁₋ₓ₎Te, CdₓZn₍₁₋ₓ₎Se, or CdₓZn₍₁₋ₓ₎S, where 0<x<1. The II-VI group semiconductor compound can also be selected from quaternary compounds such as HgZnTeS, CdZnSeS, CdZnSeTe, CdZnSTe, CdHgSeS, CdHgSeTe, CdHgSTe, HgZnSeS, HgZnSeTe, HgZnSTe, or a mixture of at least two of the above compounds, but the embodiments of the present disclosure are not limited thereto. The III-V group semiconductor compound can be selected from binary compounds such as GaN, GaP, GaAs, GaSb, AlN, AlP, AlAs, AlSb, InN, InP, InAs, and InSb, or a mixture of at least two of the above compounds; the III-V group semiconductor compound can be selected from ternary compounds such as GaNP, GaNAs, GaNSb, GaPAs, GaPSb, AlNP, AlNAs, AlNSb, AlPAs, AlPSb, InNP, InNAs, InNSb, InPAs, InPSb or a mixture of at least two of the above compounds; and the III-V group semiconductor compound can also be selected from quaternary compounds such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb, or a mixture of at least two of the above compounds, but embodiments of the present disclosure are not limited thereto. The IV-VI group semiconductor compound may be selected from, for example, the binary compounds such as SnS, SnSe, SnTe, PbS, PbSe, and PbTe, or a mixture of at least two of the above compounds; the IV-VI group semiconductor compound may be selected from the ternary compounds such as SnSeS, SnSeTe, SnSTe, PbSeS, PbSeTe, PbSTe, SnPbS, SnPbSe, and SnPbTe or a mixture of at least two of the above compounds; the IV-VI group semiconductor compound may also be selected from the quaternary compounds such as SnPbSSe, SnPbSeTe, and SnPbSTe or a mixture of at least two of the above compounds, but the embodiments of the present disclosure are not limited thereto. The I-III-VI group semiconductor compound may be, for example, CuInSe₂, CuInS₂, CuInGaSe, CuInGaS or a mixture of at least two of the above compounds, but the embodiments of the present disclosure are not limited thereto. The I-II-IV-VI group semiconductor compound may be, for example, CuZnSnSe, CuZnSnS or a mixture of the above compounds, but embodiments of the present disclosure are not limited thereto. The II-III-V group semiconductor compound may include, for example, InZnP, but embodiments of the present disclosure are not limited thereto.

For example, the quantum dot body may have a substantially uniform concentration distribution or a locally different concentration distribution, and the quantum dot body includes a mixture of the binary semiconductor compounds, the ternary semiconductor compounds, or the quaternary semiconductor compounds.

For example, as an embodiment, the quantum dot body can be a Zn—Te—Se semiconductor compound. For example, the amount of tellurium (Te) in the Zn—Te—Se semiconductor compound may be smaller than the amount of selenium (Se). The semiconductor compound may have a peak emission wavelength (λ max) in a wavelength region less than or equal to about 480 nm, for example, about 430 nm to about 480 nm, and may be configured to emit blue light.

For example, the quantum dot body may be an In—Zn—P semiconductor compound. For example, In the In—Zn—P semiconductor compound, the molar ratio of zinc (Zn) to indium (In) may be greater than or equal to about 25. The semiconductor compound may have a peak emission wavelength (λ max) in a wavelength region less than about 700 nm, for example, about 600 nm to about 650 nm, and may be configured to emit red light.

For example, the quantum dot body can have a core-shell structure, that is, nanoparticle formed by a layer of quantum dot material surrounding another quantum dot material. For example, there may be an interface between the core and the shell of the quantum dot body, and at least one element of the core or the shell in the interface may have a concentration gradient, and the concentration of the element of the shell gradually decreases towards the core. For example, the material composition of the shell of the quantum dot body has a higher energy band gap than that of the core of the quantum dot, and thus the quantum dot can exhibit a quantum confinement effect.

For example, the quantum dot body may have a quantum dot core and a plurality of quantum dot shells surrounding the core. The plurality of shells refer to at least two shells, in which each of the plurality of shells can be of a single composition, alloy, and/or a structure with a concentration gradient.

For example, a shell of the plurality of shells away from the core has a higher energy band gap than a shell of the plurality of shells close to the core, and thus the quantum dot body can exhibit quantum confinement effect.

For example, a quantum dot body having a core-shell structure may, for example, include a core including a first semiconductor compound including at least one selected from the group consisting of zinc (Zn), tellurium (Te) and selenium (Se); and a shell including a second semiconductor compound arranged on at least a part of the core and having a composition different from that of the core.

For example, the first semiconductor compound may be a semiconductor compound based on Zn—Te—Se and including zinc (Zn), tellurium (Te) and selenium (Se), for example, a semiconductor compound based on Zn—Se and including a small amount of tellurium (Te), for example, a semiconductor compound represented by ZnTexSe₍₁₋ₓ₎, where x is greater than 0 and less than or equal to 0.05.

For example, in the first semiconductor compound based on Zn—Te—Se, the molar amount of zinc (Zn) may be higher than the molar amount of selenium (Se), and the molar amount of selenium (Se) may be higher than the molar amount of tellurium (Te). For example, in the first semiconductor compound, the molar ratio of tellurium (Te) to selenium (Se) may be less than or equal to about 0.05. For example, in the first semiconductor compound, the molar ratio of tellurium (Te) to zinc (Zn) may be less than or equal to about 0.02.

For example, the second semiconductor compound may include, for example, a II-VI group semiconductor compound, a III-V group semiconductor compound, a IV-VI group semiconductor, a IV group semiconductor, a I-III-VI group semiconductor compound, a I-II-IV-VI group semiconductor compound, a II-III-V group semiconductor compound or a combination of at least two of the above compounds. Examples of the II-VI group semiconductor compound, the III-V group semiconductor compound, the IV-VI group semiconductor compound, the IV group semiconductor, the I-III-VI group semiconductor compound, the I-II-IV-VI group semiconductor compound, and the II-III-V group semiconductor compound are the same as those described above.

For example, the second semiconductor compound may include zinc (Zn), selenium (Se), and/or sulfur(S). For example, the shell may include ZnSeS, ZnSe, ZnS, or a combination thereof. For example, the shell may include at least one inner shell disposed close to the core and an outermost shell disposed at the outermost side of the quantum dot. The inner shell may include ZnSeS, ZnSe or a combination of the above compounds, and the outermost shell may include ZnS. For example, the shell may have a concentration gradient of one component, and, for example, the amount of sulfur(S) may increase with increasing distance from the core.

For example, the core of the quantum dot having a core-shell structure includes a third semiconductor compound including at least one of indium (In), zinc (Zn) and phosphorus (P); and a shell arranged on at least a part of the core and including a fourth semiconductor compound having a different composition from that of the core.

For example, in the third semiconductor compound based on In—Zn—P, the molar ratio of zinc (Zn) to indium (In) may be greater than or equal to about 25. For example, in the third semiconductor compound based on In—Zn—P, the molar ratio of zinc (Zn) to indium (In) may be greater than or equal to about 28, greater than or equal to about 29, or greater than or equal to about 30. For example, in the third semiconductor compound based on In—Zn—P, the molar ratio of zinc (Zn) to indium (In) may be less than or equal to about 55, for example, less than or equal to about 50, less than or equal to about 45, less than or equal to about 40, less than or equal to about 35, less than or equal to about 34, less than or equal to about 33, or less than or equal to about 32.

For example, the fourth semiconductor compound may include, for example, a II-VI group semiconductor compound, a III-V group semiconductor compound, a IV-VI group semiconductor, a IV group semiconductor, a I-III-VI group semiconductor compound, a I-II-IV-VI group semiconductor compound, a II-III-V group semiconductor compound or a combination of at least two of the above compounds. Examples of the II-VI group semiconductor compound, the III-V group semiconductor compound, the IV-VI group semiconductor compound, the IV semiconductor, the I-III-VI group semiconductor compound, the I-II-IV-VI group semiconductor compound, and the II-III-V group semiconductor compound may be the same as those described above.

For example, the fourth semiconductor compound may include zinc (Zn), sulfur(S) or selenium (Se). For example, the shell may include ZnSeS, ZnSe, ZnS or a combination of the above compounds. For example, the shell may include at least one inner shell disposed close to the core and a shell disposed at the outermost side of the quantum dot. At least one of the inner shell and the outermost shell may include a fourth semiconductor compound ZnS, ZnSe or ZnSeS.

For example, the quantum dot body may have a relatively deep HOMO energy level, for example, the following HOMO energy level, such as: a HOMO energy level greater than or equal to about 5.4 eV, within this range, the HOMO energy level is, for example, greater than or equal to about 5.5 eV, for example, greater than or equal to about 5.6 eV, for example, greater than or equal to about 5.7 eV, for example, greater than or equal to about 5.8 eV, for example, greater than or equal to about 5.9 eV, for example, greater than or equal to about 6.0 eV. Within this range, the HOMO energy level of the quantum dot layer may be, for example, about 5.4 eV to about 7.0 eV.

For example, the quantum dot body may have a relatively shallow LUMO energy level, for example, a LUMO energy level less than or equal to about 3.7 eV, and within this range, for example, the LUMO energy level is less than or equal to about 3.6 eV, for example, less than or equal to about 3.5 eV, for example, less than or equal to about 3.4 eV, for example, less than or equal to about 3.3 eV, for example, less than or equal to about 3.2 eV, for example, less than or equal to about 3.0 eV. Within this range, the LUMO energy level of the quantum dot layer may be about 2.5 eV to about 3.7 eV, about 2.5 eV to about 3.6 eV, about 2.5 eV to about 3.5 eV, about 2.5 eV to about 3.4 eV, about 2.5 eV to about 3.3 eV, about 2.5 eV to about 3.2 eV, about 2.5 eV to about 3.1 eV, about 2.5 eV to about 3.0 eV, about 2.8 eV to about 3.7 eV, about 2.8 eV to about 3.6 eV, about 2.8 eV to about 3.5 eV, about 2.8 eV to about 3.4 eV, about 2.8 eV to about 3.3 eV, about 2.8 eV to about 3.2 eV, about 3.0 eV to about 3.7 eV, about 3.0 eV to about 3.6 eV, about 3.0 eV to about 3.5 eV, or about 3.0 eV to about 3.4 eV.

For example, the quantum dot body may have an energy band gap of about 1.7 eV to about 2.3 eV or about 2.4 eV to about 2.9 eV. Within this range, for example, the quantum dot layer 13 may have the following energy band gap: about 1.8 eV to about 2.2 eV or about 2.4 eV to about 2.8 eV, within this range, for example, about 1.9 eV to about 2.1 eV, for example, about 2.4 eV to about 2.7 eV.

For example, in an example, the quantum dot body included in the material of the quantum dot body has a core-shell structure, in which IIB-VIA group semiconductor compounds are used as the core and the shell respectively, and the materials of the core and the shell can be binary compounds, ternary compounds or quaternary compounds respectively. For example, the materials of the core and the shell of the quantum dot can be CdSe, CdTe, ZnS, ZnSe, ZnTe, ZnO, HgS, HgSe, and HgTe, respectively.

For example, the quantum dot body with the core-shell structure includes CdSe@ZnS, CdSe@CdS, InP@ZnS, CdTe@CdSe, CdSe@ZnTeZnTe@CdSe, ZnSe@CdS, or Cd1-xZnxS@ZnS. The quantum dot body can also be ABX₃ type perovskite quantum dot body or nanocrystal, where A is one or more selected from the group consisting of CH₃NH₃⁺ (methylamine), NH₂CH═NH₂ (formamidine) and Cs+, B is one or two of Pb²⁺ and Sn²⁺, and X is one or more selected from the group consisting of Cl⁻, Br⁻, and I⁻. For example, the ABX₃ type perovskite quantum dot body includes at least one selected from the group consisting of CH₃NH₃PbBr₃, CH₃NH₃PbCl₃, CH₃NH₃PbI₃, CsPbBr₃, CsPbCl₃, and CsPbI₃. For example, it can also be other quantum dot bodies, such as CuInS₂, CuInSe₂, AgInS₂, etc., as long as the surface of the quantum dot body is coated with organic ligands.

For example, the material of the quantum dot body includes at least two metals, the material of the quantum dot body is at least one selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, CdZnSeS, CdZnSeTe, CdZnSTe, CdHgSeS, CdHgSeTe, CdHgSTe, HgZnSeS, HgZnSeTe, and HgZnSTe. Usually, when the quantum dot body is excited by a blue light source, it will emit excitation fluorescence with a specific wavelength, and its emitted fluorescence spectrum is determined by the chemical composition and particle size of the quantum dot material. With the increase of particle size of the quantum dot body, the fluorescence spectrum emitted by the material with the same chemical composition is red-shifted from green light to red light. The adopted quantum dot body material emitting red light and the quantum dot body material emitting green light can be quantum dot body materials with the same chemical composition but different particle sizes, or the adopted quantum dot body material emitting red light and the quantum dot body material emitting green light can be quantum dot body materials with different chemical compositions, that is, the quantum dot body materials in adjacent sub-pixel regions can be made of the same material but have different particle sizes, or the quantum dot body materials in adjacent sub-pixel regions can be made of different materials.

For example, the quantum dot body is a nano-level semiconductor. By applying a certain electric field or light pressure to the nano-level semiconductor material, the nano-level semiconductor material will emit light with a specific frequency, and the frequency of the emitted light will change with the size of the semiconductor, so the color of the emitted light can be controlled by adjusting the size of the quantum dot body.

For example, by controlling the shape, the structure and the size of the quantum dot body, the electronic states of the quantum dot body, such as the energy gap width, exciton binding energy and exciton energy blue shift, can be easily adjusted. With the decrease of the size of the quantum dot body, the spectrum of the quantum dot body appears blue shift. The smaller the size of the quantum dot body, the more obvious the blue shift phenomenon is. For example, for a cadmium selenide quantum dot body, the color of light emitted by cadmium selenide quantum dot body changes from red to blue when the size of the cadmium selenide quantum dot body is reduced from 10 nm to 2 nm, and the cadmium selenide quantum dot body emits blue light in a case that the size of the cadmium selenide quantum dot body is greater than or equal to 2 nm and less than 5 nm; the cadmium selenide quantum dot body emits green light in a case that the size of the cadmium selenide quantum dot body is greater than or equal to 5 nm and less than 8 nm; the cadmium selenide quantum dot body emits red light in a case that the size of the cadmium selenide quantum dot body is greater than or equal to 8 nm and less than 10 nm.

For example, the unique properties of the quantum dot body are based on its own quantum size effect. When the particle size of the quantum dot body enters the nanometer scale, the size confinement will cause size effect, quantum confinement effect, macroscopic quantum tunneling effect and surface effect, thus deriving that nano-system has low-dimensional physical properties different from micro-system, which makes that the quantum dot body has different physical and chemical properties from micro-system. For example, the quantum dot bodies have unique photoluminescence and electroluminescence properties due to quantum size effect and electric confinement effect. Compared with organic fluorescent dyes, the quantum dot materials have excellent optical characteristics, such as high quantum yield, high photochemical stability, difficult photolysis, wide excitation, narrow emission, high color purity, and the luminous color can be adjusted by controlling the size of the quantum dot body. In this way, quantum dot light emitting devices including the quantum dot light emitting layers have the advantages of high luminous efficiency, good stability, long life, high brightness and wide color gamut.

For example, in the quantum dot composition provided by at least one embodiment of the present disclosure, the first quantum dot ligand is mainly composed of three parts, and its general formula is D-E-F, where D is an anchoring group that can be grafted on the surface of the quantum dot; E is a connection group, for example, alkyl or polyether segments (such as oligomer polyethylene oxide, etc.), or E is an alkyl group with one or more double bonds or benzene ring groups; F is a functional group. For example, the first quantum dot ligand includes a coordination group D combined with the surface of the quantum dot body, a first connection group E connected with the coordination group D, and a first functional group F connected with the first connection group E. The first connection group E can play a role in connecting the first functional group F and the first connection group E.

For example, in an example, the coordination group D may be one or more selected from the group consisting of sulfhydryl (—SH), carboxyl (—COOH), amino (—NH₂), phosphino (—P—) and phosphono (—P═O). The first connection group E is at least one selected from the group consisting of linear alkyl containing C1-C30, unsaturated hydrocarbon chain with one or more double bonds or benzene rings, and polyether segment compound. For example, the first connection group E is an alkyl chain containing less than 10 carbon atoms, which may contain one or more double bonds or phenyl groups. The first functional group F may be at least one selected from the group consisting of methyl, phenyl, sulfonic acid, carboxyl, nitroso, cyano, hydroxyl, amide, phenolic hydroxyl, sulfhydryl, amino, aldehyde, carbonyl, alkenyl, alkynyl, ether bond and thioether bond. The corresponding first quantum dot ligand is at least one selected from the group consisting of oleic acid, oleylamine, sulfhydrylpropionic acid, sulfhydrylethanol, 1-1-dodecanethiol, 1-octanethiol, 6-mercaptohexanol, stearic acid, ethylenediamine, ethanethiol, thiophenol and hydroquinone (including ortho-para), etc.

For example, in a case that the first functional group F is a strongly polar group, the first functional group F can be at least one selected from the group consisting of sulfonic acid, carboxyl, nitroso, cyano, hydroxyl, amide, phenolic hydroxyl, sulfhydryl and amino.

For example, in a case that the first functional group F is a weakly polar group, the first functional group F can be at least one selected from the group consisting of methyl, phenyl group, and aldehyde, and the first functional group F can contain one or more other weakly polar intermediate groups, such as at least one of carbonyl, alkenyl, alkynyl, ether bond, thioether bond, etc.

For example, in another example, the first quantum dot ligand can also be mainly composed of two parts, and its general formula is D-E, where D is an anchoring group that can be grafted on the surface of the quantum dot; E is a connection group, for example, alkyl or polyether segments (such as oligomer polyethylene oxide, etc.), or E is an alkyl group with one or more double bonds or benzene ring groups, that is, the first quantum dot ligand may not have functional groups. For example, the first quantum dot ligand includes a coordination group D combined with the surface of the quantum dot body, and a first connection group E connected with the coordination group D. The selection of the coordination group D and the first connection group E can be found in the above description, which will not be repeated herein.

For example, in the quantum dot composition, the polarity of the quantum dot is determined by the polarity of the first quantum dot ligand connected to the quantum dot body. The more the number of the coordination groups D in the first quantum dot ligand, the stronger the binding force between the first quantum dot ligand and the quantum dot body. The less carbon atoms in the first connection group E, the more favorable it is to enhance the polarity of the first quantum dot ligand, and the more carbon atoms, the more favorable it is to enhance the non-polarity of the first quantum dot ligand.

For example, in an example, the photosensitizer is an organic substance that can undergo photochemical reaction after illumination, and its general formula is, for example, A-B-C. The photosensitizer includes a photosensitive group A, a second connection group B connected to the photosensitive group A, and a second functional group C connected to the second connection group B. The first functional group F included in the first quantum dot ligand and the second functional group C included in the photosensitizer have different polarities, or the first quantum dot ligand does not include the first functional group, that is, the first quantum dot ligand is nonpolar, and the second functional group C included in the photosensitizer has strong polarity. For example, the above photochemical reactions mainly include hydrocarbon insertion reaction and carbon-carbon double bond addition reaction. Through the hydrocarbon insertion reaction or the carbon-carbon double bond addition reaction, the polarity of the first quantum dot ligand of the quantum dot can be changed after being connected with the second functional group C in the photosensitizer, so as to achieve the purpose of subsequent photolithography patterning of a quantum dot film, and at the same time, the molecular weight of the second quantum dot ligand can be made larger than the molecular weight of the first quantum dot ligand.

For example, the more the photosensitive groups A included in the photosensitizer, the higher the sensitivity of the photosensitizer, and the lower the amount of light required to obtain the quantum dot patterns. The less the number of carbon atoms in the second connection group B, the more favorable it is to enhance the polarity of the illuminated quantum dots, and the more the number of the carbon atoms, the more favorable it is to enhance the non-polarity of the illuminated quantum dots. The more the number of second functional groups C is, the easier it is to change the polarity and solubility of the quantum dots after illumination.

For example, in the embodiment of the present disclosure, the above-mentioned hydrocarbon insertion reaction and carbon-carbon double bond addition reaction mainly occur on the first connection group E, that is, when the above-mentioned hydrocarbon insertion reaction and the carbon-carbon double bond addition reaction are carried out, it is not needed to change the coordination group D included in the first quantum dot ligand, and it is not needed to realize the change of quantum dot solubility by peeling off the first quantum dot ligand. If the first quantum dot ligand falls off from the quantum dot body, it will lead to the phenomenon of surface defects of the quantum dot body, thus reducing the probability of exciton radiation recombination, which is further unfavorable in the application of display aspects. The embodiment of the present disclosure can basically maintain the original environment of the first quantum dot ligand by changing some functional groups of the first quantum dot ligand, for example, changing the first connection group E to make the molecular weight of the second quantum dot ligand larger than the molecular weight of the first quantum dot ligand, without reducing or crosslinking the coordination group D and the first connection group E, so the influence on the performance of the finally formed electroluminescent device is limited. That is, the coordination group D included in the first quantum dot ligand is not changed, so that the interaction between the first quantum dot ligand and the quantum dot body will not be affected, and the phenomenon that the first quantum dot ligand falls off from the surface of the quantum dot body will not be caused, so that defects will not be introduced. After the lithography composition is irradiated, the first quantum dot ligand can still effectively passivate the surface defects, which is beneficial to maintaining the photoelectric properties of the quantum dots.

For example, in an example, the first quantum dot ligand includes a C—H bond, the photosensitive group is configured to form at least one of nitrogen carbene, carbonyl radical and carbene under illumination, and at least one of the nitrogen carbene, carbonyl radical and carbene undergoes a hydrocarbon insertion reaction with the C—H bond included in the first quantum dot ligand to form the second quantum dot ligand. For example, the photosensitive group reacts with the C—H bond included in the first quantum dot ligand under illumination to form the second quantum dot ligand, and the second functional group C included in the photosensitizer replaces the first functional group F in the first quantum dot ligand, or the second functional group C included in the photosensitizer is formed on the first quantum dot ligand without the first functional group, so that the polarity of the second quantum dot ligand is different from the polarity of the first quantum dot ligand.

For example, carbene, also known as carbon alkene, is formed by eliminating a neutral molecule from a molecule containing an easy-to-leave group. Like carbon free radicals, carbene belongs to neutral active intermediates without positive charges and negative charges. Carbene is the generic term for H₂C: and its substituted derivatives. Carbene contains an electrically neutral divalent carbon atom with two unbound electrons, which is a highly active intermediate containing two unbound electrons.

For example, the higher the sensitivity of the photosensitizer, the lower the amount of light required to obtain quantum dot pattern. The more the number of the second functional groups C is, the greater the change of solubility of quantum dots before and after illumination.

For example, in an example, the photosensitive group included in the second quantum dot ligand includes at least one selected from the group consisting of azide, benzophenone and diazirine. The photosensitive group makes the quantum dot composition produce photosensitive intermediates, such as nitrogen carbene, carbonyl radical, carbene and so on, after ultraviolet illumination.

For example, in an example, the quantum dot ligand includes a C═C bond, and the photosensitive group is configured to undergo an addition reaction with the C═C bond included in the first quantum dot ligand under illumination to form a second quantum dot ligand, so that the molecular weight of the second quantum dot ligand is greater than the molecular weight of the first quantum dot ligand.

For example, in an example, the photosensitive group forms a nitrogen carbene under illumination, and the nitrogen carbene reacts with the C═C bond included in the first quantum dot ligand to form the second quantum dot ligand, and the second functional group C included in the photosensitizer replaces the first functional group F in the first quantum dot ligand, or the second functional group C included in the photosensitizer is formed on the first quantum dot ligand without the first functional group, so that the polarity of the second quantum dot ligand is different from the polarity of the first quantum dot ligand.

For example, in an example, the photosensitive group includes azide, so that under the illumination of ultraviolet light, azide can not only undergo hydrocarbon insertion reaction, but also undergo carbon-carbon double bond addition reaction, that is,

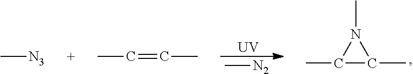

the nitrogen carbene, a photosensitive intermediate, is produced. For example, the photosensitive group may include one or more azides.

For example, in an example, the second connection group includes a C1-C30 linear alkyl, or an unsaturated hydrocarbon chain with one or more double bonds or benzene rings. The second functional group includes at least one selected from the group consisting of sulfonic acid, carboxyl, nitroso, cyano, hydroxyl, amide, phenolic hydroxyl, sulfhydryl, amino, methyl, aldehyde, alkyl, carbonyl, alkenyl, alkynyl, ether bond and thioether bond. The second connection group B can play a role in connecting the second functional group C and the photosensitive group A.

For example, in an example, the second functional group is a strongly polar group, and correspondingly, the first functional group is a weakly polar group. For example, the second functional group is at least one selected from the group consisting of sulfonic acid, carboxyl, nitroso, cyano, hydroxyl, amide, phenolic hydroxyl, sulfhydryl and amino, and the first functional group is at least one selected from the group consisting of methyl, aldehyde, carbonyl, alkenyl, alkynyl, ether bond and thioether bond, but the embodiment of the present disclosure is not limited thereto, as long as the polarity of the second functional group is greater than the polarity of the first functional group.

For example, in another example, the second functional group is a weakly polar group, and correspondingly, the first functional group is a strongly polar group. For example, the second functional group is at least one selected from the group consisting of methyl, aldehyde, alkyl, carbonyl, alkenyl, alkynyl, ether bond and thioether bond, and the first functional group is at least one selected from the group consisting of phenyl, sulfonic acid, carboxyl, nitroso, cyano, hydroxyl, amide, phenolic hydroxyl, sulfhydryl and amino, but the embodiment of the present disclosure is not limited thereto, as long as the polarity of the second functional group is less than the polarity of the first functional group.

For example, the quantum dot composition provided by at least one embodiment of the present disclosure further includes a solvent, which is a weakly polar solvent or a nonpolar solvent, and the first functional group is a weakly polar group or a nonpolar group, so that the quantum dot material can be fully dissolved in the weakly polar solvent or the nonpolar solvent before illumination. The corresponding second functional group is a strongly polar group, which can make the polarity of the second quantum dot ligand on the surface of the quantum dot different from the polarity of the first quantum dot ligand after illumination, and a dielectric constant of the weakly polar solvent or the nonpolar solvent is less than 3.6.

For example, in an example, the weakly polar solvent or nonpolar solvent includes at least one selected from the group consisting of cyclohexane, petroleum ether, octane, trimethylpentane, carbon tetrachloride, trichlorotrifluoroethane, p-xylene, chlorobenzene, o-dichlorobenzene, diethyl ether, diethoxyethane, tetrahydrofuran, hexane, pentane, toluene and chlorobenzene, but the embodiments of the present disclosure are not limited thereto, and other weakly polar solvents or nonpolar solvents can also be used.

For example, in an example, the first quantum dot ligand is 1-octanethiol or oleic acid, the corresponding photosensitizer is 2,3,4,5-tetrafluoro-4-azidebenzoic acid or 3-benzoyl benzoic acid, and the solvent is the weakly polar solvent or the nonpolar solvent.

For example, the quantum dot composition provided by at least one embodiment of the present disclosure further includes a solvent, which is a strongly polar solvent, and the first functional group is strongly polar, so that the quantum dot material can be fully dissolved in the strongly polar solvent before illumination. The corresponding second functional group is weakly polar or nonpolar, and the dielectric constant of the strongly polar solvent is greater than or equal to 3.6.

For example, in an example, the first quantum dot ligand is 6-mercaptohexanol, the corresponding photosensitizer is 2,3,4,5-tetrafluoro-4-azido octadecyl benzene, and the solvent is a strongly polar solvent.

For example, in an example, the strongly polar solvent includes at least one of methanol, ethanol, isopropanol, ethyl acetate, acetonitrile, acetone, acetic acid, pyridine, N,N-dimethylformamide and dimethyl sulfoxide, but the embodiments of the present disclosure are not limited thereto, and other strongly polar solvents can be used.

At least one embodiment of the present disclosure also provides a patterning method of a quantum dot film, which includes: providing a substrate; applying the quantum dot composition in any one of the above embodiments on the substrate to form a quantum dot film; shielding the quantum dot film with a mask plate, and irradiating a partial region of the quantum dot film with light to increase the molecular weight of the quantum dot ligand and change the polarity of the quantum dot ligand in the partial region; developing the quantum dot film with a developer to obtain a patterned quantum dot film. The patterning method of the quantum dot film provided by the embodiment of the present disclosure has a simple process, and the direct lithography patterning is carried out by using the surface chemical properties of the quantum dot, thus avoiding the damage of the introduction of photoresist to the photoelectric properties of the quantum dots, and the subsequent development mode is flexible. By selecting solvents with different polarities for development, the quantum dot film with a positive pattern or a negative pattern can be obtained.

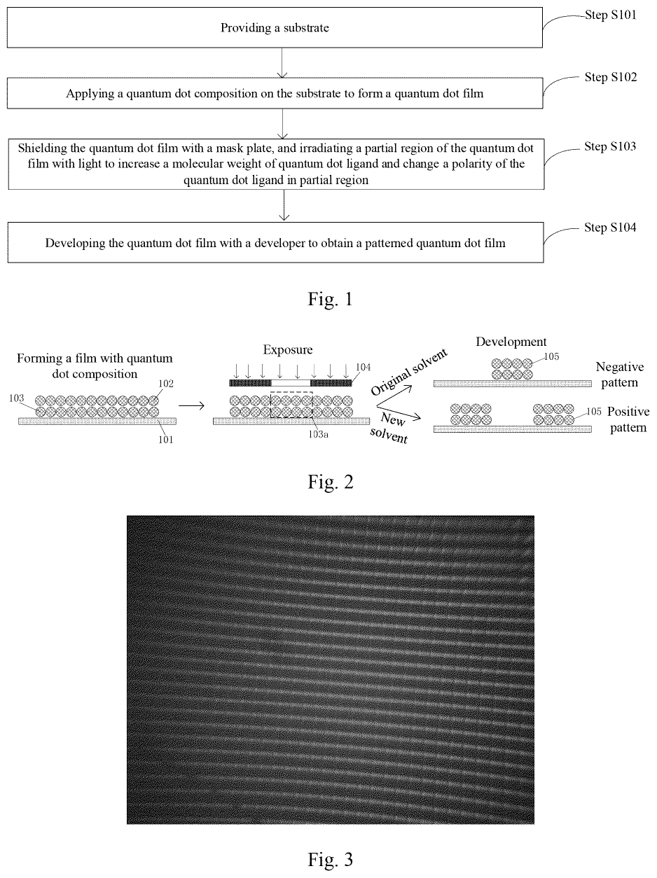

For example, FIG. 1 is a flowchart of a patterning method of a quantum dot film provided by at least one embodiment of the present disclosure. As illustrated by FIG. 1, the patterning method of the quantum dot film includes the following steps.

Step S101: providing a substrate.

For example, the substrate includes a rigid substrate or a flexible substrate, and the material of the substrate may include glass, plastic or other materials, which is not limited by the embodiment of the present disclosure.

Step S102: applying a quantum dot composition on the substrate to form a quantum dot film.

For example, the quantum dot composition includes a quantum dot material and a photosensitizer which are mixed, the quantum dot material includes a quantum dot body and a first quantum dot ligand on a surface of the quantum dot body; the photosensitizer is configured to react with the first quantum dot ligand under illumination to form a second quantum dot ligand; a molecular weight of the second quantum dot ligand is greater than a molecular weight of the first quantum dot ligand; and a polarity of the second quantum dot ligand is different from a polarity of the first quantum dot ligand. For example, the photosensitizer includes a photosensitive group, a second connection group connected with the photosensitive group, and a second functional group connected with the second connection group. Before illumination, the photosensitizer can form a mixed solution with the quantum dot material. After film coating and illumination, the photosensitive group in the photosensitizer reacts with the first quantum dot ligand, so that the photosensitive group is grafted on the first quantum dot ligand to achieve the purpose and effect of changing the polarity of the quantum dot surface ligand.

For example, applying the quantum dot composition on the substrate includes blade coating, spin coating or spray coating the quantum dot composition on the substrate to form the quantum dot film.

Step S103: shielding the quantum dot film with a mask plate, and irradiating a partial region of the quantum dot film with light to increase a molecular weight of quantum dot ligand and change a polarity of the quantum dot ligand in partial region.

For example, the mask plate includes a light-transmitting region and a light-shielding region, and the light-transmitting region can transmit light and make the transmitted light irradiate the partial region of the quantum dot film. The irradiating the partial region of the quantum dot film with light to increase the molecular weight of the ligand on the surface of the quantum dot body and change the polarity of the ligand on the surface of the quantum dot body in the partial region being irradiated includes: shielding the quantum dot film with a mask plate, and irradiating the partial region of the quantum dot film with ultraviolet light or infrared light to increase the molecular weight of the ligand on the surface of the quantum dot body to form a second quantum dot ligand in the partial region being irradiated by the ultraviolet light or infrared light. That is, the light transmitted from the light-transmitting region irradiates the partial region of the quantum dot film, so that the first quantum dot ligand included in the quantum dot material in the partial region being irradiated reacts with the photosensitizer to form the second quantum dot ligand, the molecular weight of the second quantum dot ligand is larger than the molecular weight of the first quantum dot ligand, and the polarity of the quantum dot ligand can be changed, that is, the embodiment of the present disclosure uses the property that the polarity of the original quantum dot ligand is changed after being connected with a specific group in the photosensitizer to achieve the purpose of lithography patterning of the quantum dot film.

Step S104: developing the quantum dot film with a developer to obtain a patterned quantum dot film.

For example, FIG. 2 is a process diagram of a patterning method of a quantum dot film provided by at least one embodiment of the present disclosure. As illustrated by FIG. 2, the patterning method of the quantum dot film includes the following process steps.

Process step 1: applying the quantum dot composition 102 on the substrate 101 to form the quantum dot film 103.

For example, applying the quantum dot composition 102 on the substrate 101 includes blade coating, spin coating or spray coating the quantum dot composition on the substrate 101 to form the quantum dot thin film 103.

Process step 2: shielding the quantum dot film 103 with a mask plate 104, and irradiating a partial region 103a of the quantum dot film 103 with ultraviolet light or infrared light to increase the molecular weight of the ligand on the surface of the quantum dot body and change the polarity of the ligand on the surface of the quantum dot body in the exposed partial region 103a.

For example, the polarity of the ligand on the surface of the quantum dot body in the exposed partial region 103a is different from the polarity of the ligand on the surface of the quantum dot body in the unexposed region, which will lead to different solubility of quantum materials in the corresponding solvents. That is, ultraviolet light or infrared light irradiates a partial region 103a of the quantum dot film 103, so that the first quantum dot ligand on the surface of the quantum dot body in the quantum dot composition 102 can react with the photosensitizer to form a second quantum dot ligand, and the molecular weight of the second quantum dot ligand is greater than the molecular weight of the first quantum dot ligand, and the polarity of the second quantum dot ligand is different from the polarity of the first quantum dot ligand.

Process step 3: developing the quantum dot film 103 with a developer to obtain a patterned quantum dot film 105.

For example, the quantum dot thin film 103 may be developed with a negative developer or the quantum dot thin film 103 may be developed with a positive developer. For example, the negative developer can be used to remove the quantum dot film in a region except the illumination region to obtain a patterned quantum dot film 105, that is, a solvent with a polarity similar to that in the quantum dot material before illumination is used as the developer, and the quantum dot material in the non-illumination region is washed away by the developer, leaving the quantum dot material in the illumination region to obtain a negative pattern; alternatively, the positive developer is used to remove the quantum dot material in the illumination region to obtain the patterned quantum dot film 105, that is, a specific solvent that can dissolve the quantum dot material in the illumination region is selected as the developer, and the quantum dot material in the illumination region can be washed away to obtain a positive pattern.

For example, the patterned quantum dot film 105 corresponding to a first color is formed by the above process step 1 to step 3, and then the patterned quantum dot film 105 corresponding to a second color and the patterned quantum dot film 105 corresponding to a third color are formed by repeating the above process step 1 to step 3, that is, a full-color pattern is formed.

For example, in an example, the first functional group of the first quantum dot ligand is a weakly polar group or a nonpolar group, and the second functional group of the corresponding photosensitizer is a strongly polar group, so that the ligand on the surface of the quantum dot body changes from weak polarity or nonpolar to strong polarity. Before the first quantum dot ligand and the photosensitizer react, the polarity of the solvent of the quantum dot material is similar to that of the first quantum dot ligand, and the solvent of the quantum dot material before the reaction is called as original solvent, and other solvent with different polarity from the original solvent is called as new solvent. For example, the polarity of the original solvent is weak polarity or nonpolar, and the polarity of the new solvent is strong polarity. When a negative developer is used to form a negative pattern, the solvent in the developer can be the original solvent, that is, the polarity of the solvent in the developer is similar to that of the first quantum dot ligand, and both are weak polarity or nonpolar. In a case that a positive developer is used to form a positive pattern, the solvent in the developer can be a new solvent, that is, the polarity of the solvent in the developer is different from that of the first quantum dot ligand, the polarity of the first quantum dot ligand is weak polarity or nonpolar, and the polarity of the solvent in the developer is strong polarity.

For example, in another example, the first functional group of the first quantum dot ligand is a strongly polar group, and the second functional group of the corresponding photosensitizer is a weakly polar group or a nonpolar group, so that the ligand on the surface of the quantum dot body changes from strong polarity to weak polarity or non-polarity. Before the first quantum dot ligand reacts with the photosensitizer, the polarity of the solvent of the quantum dot material is similar to that of the first quantum dot ligand, and the solvent of the quantum dot material before the reaction is called as the original solvent, and other solvent with different polarity from the original solvent is called as new solvent. For example, the polarity of the original solvent is strong, and the polarity of the new solvent is weak or nonpolar. In a case that a negative developer is used to form a negative pattern, the solvent in the developer can be the original solvent, that is, the polarity of the solvent in the developer is similar to that of the first quantum dot ligand, and both are strong. In a case that a positive developer is used to form a positive pattern, the solvent in the developer can be a new solvent, that is, the polarity of the solvent in the developer is different from that of the first quantum dot ligand, the polarity of the first quantum dot ligand is strong, and the polarity of the solvent in the developer is weak or nonpolar.

For example, in the patterning method of the quantum dot film provided by the embodiment of the present disclosure, the first quantum dot ligand on the surface of the quantum dot body and the photosensitizer are directly subjected to hydrocarbon insertion reaction or carbon-carbon double bond addition reaction under illumination, so that the polarity of the first quantum dot ligand can be changed after the second functional group in the photosensitizer is connected, so that the purpose of photolithography patterning of the quantum dot film can be achieved subsequently. At the same time, the molecular weight of the second quantum dot ligand can be made larger than that of the first quantum dot ligand, that is, the ligand exchange is not needed, so that the processing steps are reduced, and the properties of the first quantum dot ligand connected with the quantum dot body are kept as much as possible, and the photoresist process is not needed, so that the principle and composition of the patterning method are simple, and the quantum dot composition is only composed of quantum dots and photosensitizers. In addition, the patterning method is universal, and the photosensitizer can pattern the quantum dot material formed by the quantum dot body and the first quantum dot ligand with different component structures. In addition, according to the change of the polarity of ligands on the surface of the quantum dot body before and after illumination, the quantum dot composition can be designed as a positive quantum dot composition, that is, the quantum dots in the illumination region are developed.

For example, in another embodiment of the present disclosure, the polarity of the quantum dot ligand is less than that of the photosensitizer, and forming the patterned quantum dot film includes removing the quantum dot film in the region except the illumination region with a nonpolar negative developer to obtain a patterned quantum dot film.

For example, in another embodiment of the present disclosure, the polarity of the quantum dot ligand is less than that of the photosensitizer, and forming the patterned quantum dot film includes removing the quantum dot film in the illumination region with a polar positive developer to obtain the patterned quantum dot film.

For example, in another embodiment of the present disclosure, the polarity of the quantum dot ligand is greater than that of the photosensitizer, and forming the patterned quantum dot film includes removing the quantum dot film in the region except the illumination region by using a polar negative developer to obtain the patterned quantum dot film.

For example, in another embodiment of the present disclosure, a nonpolar positive developer is used to remove the quantum dot film in the illumination region to obtain the patterned quantum dot film.

For example, in the first embodiment, before the quantum dot film is irradiated by ultraviolet light or infrared light, the first quantum dot ligand on the surface of the quantum dot body has strong polarity, the photosensitizer is nonpolar or weakly polar, and the developer is nonpolar or weakly polar, and the patterned quantum dot film is formed by positive photoresist patterning. For example, the composition of quantum dot composition includes red quantum dot body CdSe/ZnS, the first quantum dot ligand on the surface of red quantum dot body is a strongly polar ligand of 6-mercaptohexanol, the photosensitizer is a weakly polar organic molecule of 2,3,4,5-tetrafluoro-4-azido octadecyl benzene, and the solvent is ethanol. Spin coating the quantum dot composition on a substrate to form a quantum dot film, the mass and volume concentrations of the quantum dot material and the photosensitizer are 25 g/L and 0.5 g/L, respectively. The quantum dot film is shielded by a mask plate, and a partial region of the quantum dot film is irradiated by ultraviolet light, that is, the partial region is exposed by ultraviolet light for 20 seconds. Because many long alkyl chains are grafted on the first quantum dot ligand of 6-mercaptohexanol on the surface of the quantum dot body in the process of ultraviolet exposure to form the second quantum dot ligand, that is, the ligand on the surface of the quantum dot body in the illumination region is changed from a strongly polar ligand to a weakly polar ligand, the quantum dot material in the illumination region is no longer soluble in the original alcohol solvent with strong polarity, but can be dissolved in a nonpolar solvent, such as toluene. Therefore, if the patterned quantum dot film is developed with toluene, the quantum dot material in the illumination region will be washed away, and the quantum dot material in the non-illumination region is retained to realize the positive photoresist patterning.

For example, because the 6-mercaptohexanol includes a plurality of carbon-hydrogen bonds, chemical reactions can occur at any position of carbon-hydrogen bonds on 6-mercaptohexanol, and various types of chemical reactions can occur according to the different positions of hydrocarbon insertion reaction, that is, the reaction positions are not fixed, and the reaction products are not unique. For example, the chemical reaction formula corresponding to the first embodiment is:

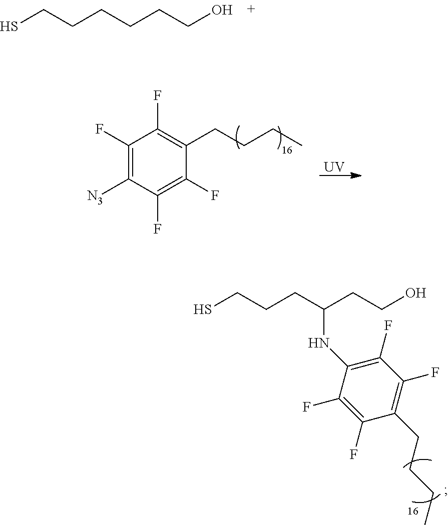

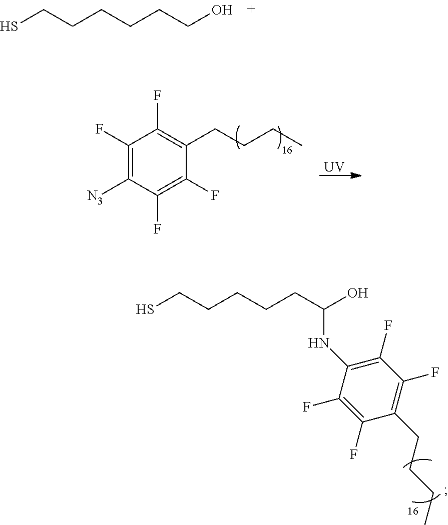

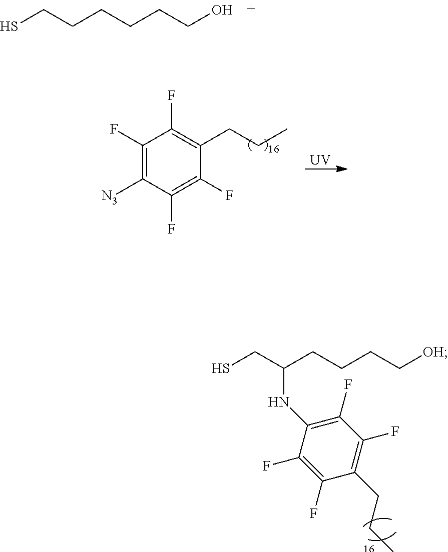

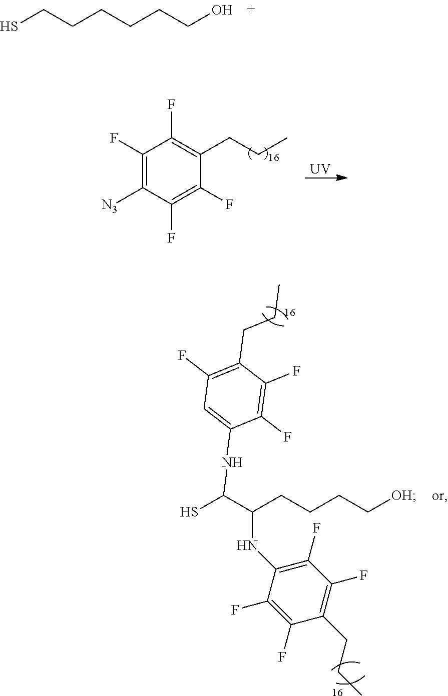

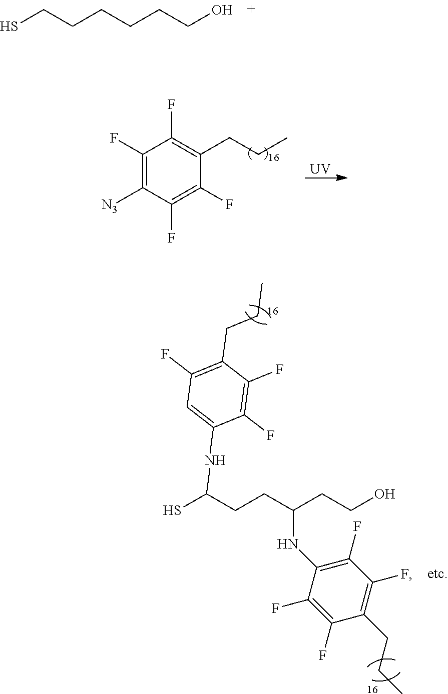

For example, in the second embodiment, before the quantum dot film is irradiated by ultraviolet light or infrared light, the first quantum dot ligand on the surface of the quantum dot body has strong polarity, the photosensitizer is nonpolar or weakly polar, and the developer is strongly polar, and the patterned quantum dot film is formed by negative photoresist patterning. For example, the composition of the quantum dot composition includes a red quantum dot body CdSe/ZnS, a first quantum dot ligand on the surface of red quantum dot body is strongly polar ligand of 6-mercaptohexanol, the photosensitizer is a weakly polar organic molecule of 2,3,4,5-tetrafluoro-4-azido octadecyl benzene, and the solvent is ethanol. Spin coating the quantum dot composition on a substrate to form a quantum dot film, the mass and volume concentrations of the quantum dot material and the photosensitizer are 25 g/L and 0.5 g/L, respectively. The quantum dot film is shielded by a mask plate, and a partial region of the quantum dot film is irradiated by ultraviolet light, that is, the partial region is exposed by ultraviolet light for 20 seconds. Because many long alkyl chains are grafted on the first quantum dot ligand of 6-mercaptohexanol on the surface of the quantum dot body in the process of ultraviolet exposure to form the second quantum dot ligand, that is, the ligand on the surface of the quantum dot body in the illumination region is changed from a strongly polar ligand to a weakly polar ligand, the quantum dot material in the illumination region is no longer dissolved in the original alcohol solvent with strong polarity, but the quantum dot material in the non-illumination region is still dissolved in a strongly polar solvent, such as ethanol. If the patterned quantum dot film is developed with ethanol, the quantum dot material in the non-illumination region is washed away, leaving the quantum dot material in the illumination region to realize negative photoresist patterning.

For example, because 6-mercaptohexanol includes a plurality of carbon-hydrogen bonds, chemical reactions can occur at any position of carbon-hydrogen bonds on 6-mercaptohexanol, and various types of chemical reactions can occur according to different positions of hydrocarbon insertion reaction, that is, the reaction positions are not fixed, and the reaction products are not unique. For example, the chemical reaction formula corresponding to the second embodiment is:

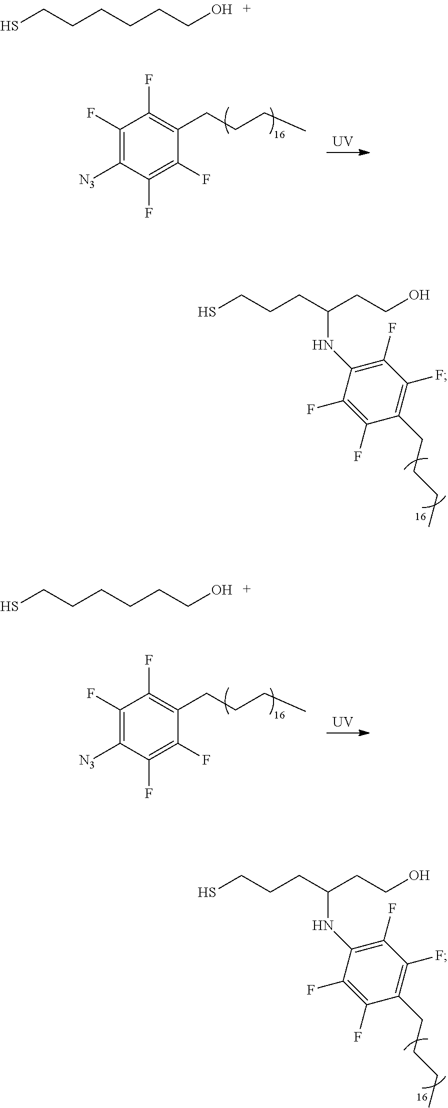

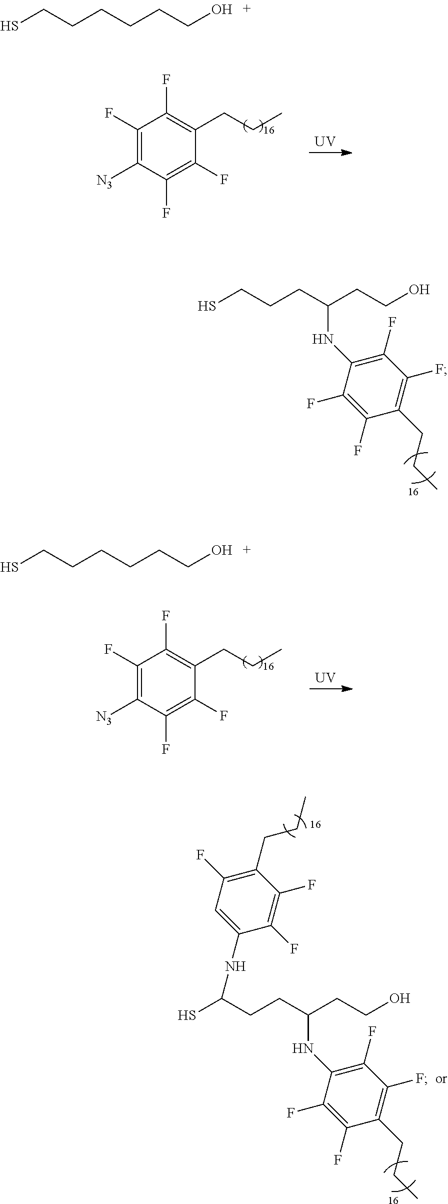

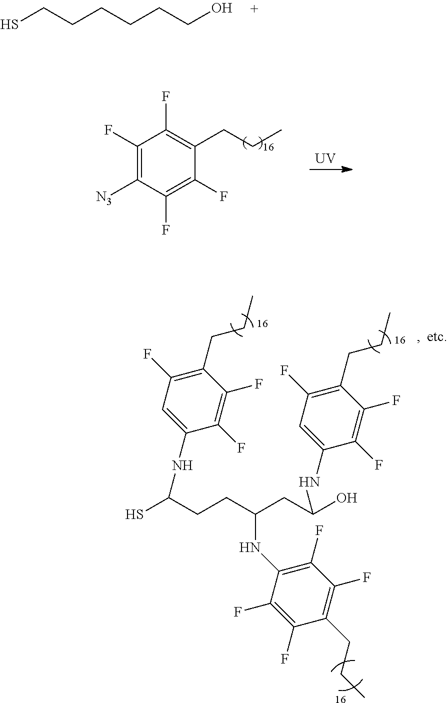

For example, in the third embodiment, before the quantum dot film is irradiated by ultraviolet light or infrared light, the first quantum dot ligand on the surface of the quantum dot body is nonpolar or weakly polar, the photosensitizer has strong polarity, and the developer has strong polarity, and the patterned quantum dot film is formed by positive photoresist patterning. For example, the components of the quantum dot composition include red quantum dot body CdSe/ZnS, the first quantum dot ligand on the surface of the red quantum dot body is a weakly polar ligand of 1-octanethiol, the photosensitizer is a strongly polar organic molecule of 2,3,4,5-tetrafluoro-4-azidebenzoic acid or 3-benzoyl benzoic acid, and the solvent is nonpolar solvent toluene. Spin coating the quantum dot composition on a substrate to form a quantum dot film, the mass and volume concentrations of the quantum dot material and the photosensitizer are 25 g/L and 0.5 g/L, respectively. The quantum dot film is shielded by a mask plate, and a partial region of the quantum dot film is irradiated by ultraviolet light, that is, the partial region is exposed by ultraviolet light for 20 seconds, and a positive pattern is obtained by immersion and development with acetone. Because the photosensitizer 2,3,4,5-tetrafluoro-4-azidebenzoic acid or 3-benzoyl benzoic acid is connected to the first quantum dot ligand I-octanethiol on the surface of the quantum dot body to form the second quantum dot ligand in the process of ultraviolet exposure, and because the photosensitizer contains the carboxyl with strong polarity, the polarity of the ligand on the surface of the quantum dot body becomes stronger after ultraviolet exposure, so it can be dissolved in polar solvents such as acetone. After ultraviolet illumination, the quantum dot material in the illumination region can be development and removed by acetone, and the pattern of the quantum dot film cannot be retained in the illumination region. However, the first quantum dot ligand of 1-octanethiol on the surface of the quantum dot body before illumination is a weakly polar group, which is insoluble in polar solvents such as developer acetone. Therefore, the quantum dot material in the non-illumination region is retained, and the positive patterning effect is achieved.

For example, because 1-octanethiol includes a plurality of carbon-hydrogen bonds, chemical reactions can occur at any position of carbon-hydrogen bonds on 1-octanethiol, and various types of chemical reactions can occur according to different positions of hydrocarbon insertion reaction, that is, the positions of the reactions are not fixed and the products of the reactions are not unique. For example, the chemical reaction formula corresponding to third embodiment is:

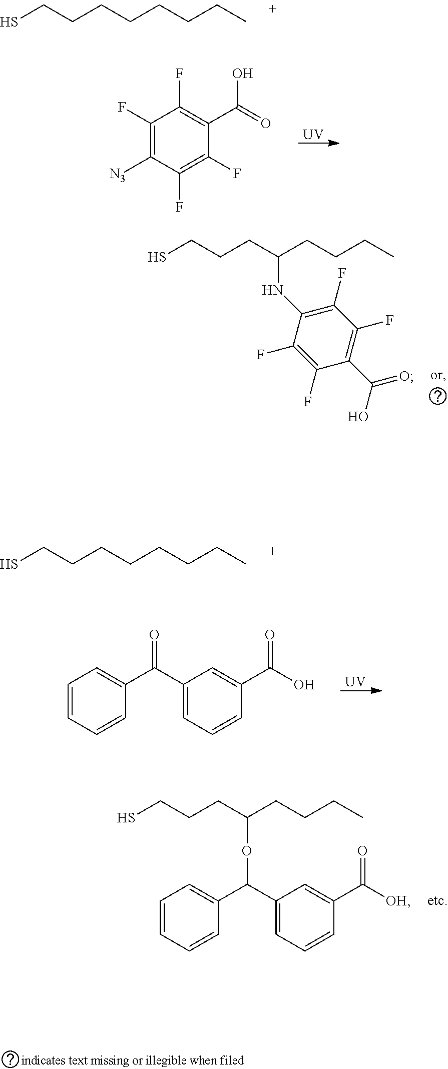

For example, in the fourth embodiment, before the quantum dot film is irradiated by ultraviolet light or infrared light, the first quantum dot ligand on the surface of the quantum dot body is nonpolar or weakly polar, the photosensitizer is strongly polar, and the developer is nonpolar or weakly polar, and the patterned quantum dot film is formed by negative photoresist patterning. For example, the components of the quantum dot composition include red quantum dot body CdSe/ZnS, the first quantum dot ligand on the surface of the red quantum dot body is a nonpolar ligand of oleic acid, the photosensitizer is a strongly polar organic molecule of 2,3,4,5-tetrafluoro-4-azidebenzoic acid, and the solvent is nonpolar solvent toluene. Spin coating the quantum dot composition on a substrate to form a quantum dot film, the mass and volume concentrations of the quantum dot material and the photosensitizer are 25 g/L and 0.5 g/L, respectively. The quantum dot film is shielded by a mask plate, and a partial region the quantum dot film is irradiated by ultraviolet light, that is, the partial region is exposed by ultraviolet light for 20 seconds, and a negative pattern is obtained by immersion and development with toluene. For example, FIG. 3 is a fluorescence microscope picture of a quantum dot film formed by the patterning method of the quantum dot film provided by the fourth embodiment of the present disclosure. It can be seen form FIG. 3 that the pattern of the red quantum dot film in the region irradiated by ultraviolet light is complete and clear, and the pixels in other regions not irradiated by ultraviolet light cannot emit red light, thus indicating that the photosensitizer generates nitrogen carbene through azide photolysis after exposure in the region irradiated by ultraviolet light. Nitrogen carbene is connected to the surface of the quantum dot body by hydrocarbon insertion reaction with the surface ligand of oleic acid of the quantum dot body, so that carboxylic acid functional groups are grafted on the surface of the quantum dot body, so that the polarity of the surface ligand of the quantum dot body is changed, that is, the nonpolar alkyl chain included in the original oleic acid is changed into an alkyl chain connected with carboxyl, and the polarity change is so great that the quantum dot material in the illumination region is no longer dissolved in the original solvent toluene. Moreover, the thickness of the red pixel pattern obtained by the method in the fourth embodiment is 18 nm as measured by a step meter.

For example, because oleic acid contains a plurality of carbon-hydrogen bonds, chemical reactions can occur at any position of carbon-hydrogen bonds on oleic acid, and various types of chemical reactions can occur according to the different positions of hydrocarbon insertion reaction, that is, the positions of the reactions are not fixed and the products of the reactions are not unique. For example, the chemical reaction formula corresponding to fourth embodiment is:

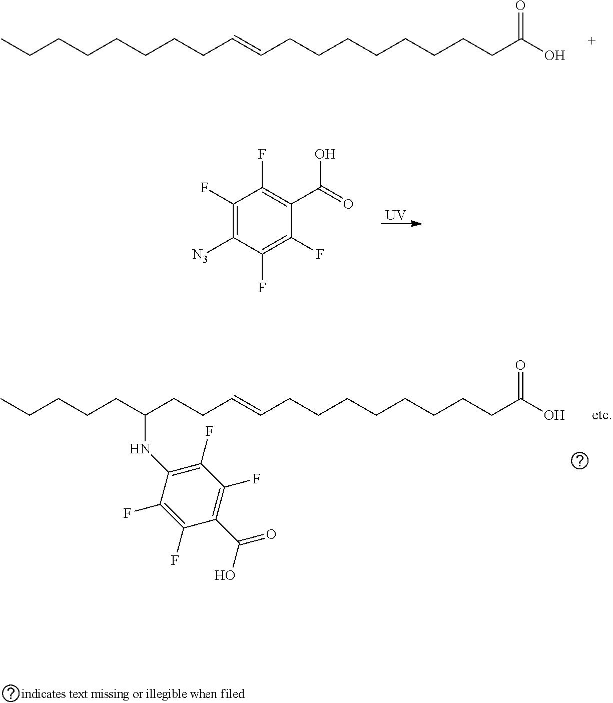

For example, in the fourth embodiment above, because the photosensitizer 2,3,4,5-tetrafluoro-4-azidebenzoic acid is connected to the first quantum dot ligand oleic acid on the surface of the quantum dot body to form the second quantum dot ligand during the ultraviolet exposure, and because the photosensitizer contains a carboxyl with strong polarity, the polarity of the ligand on the surface of the quantum dot body becomes larger after the ultraviolet exposure, that is, the ligand on the surface of the quantum dot body in the illumination region changes from a weak polarity ligand to a strong polarity ligand. The quantum dot material in the illumination region is no longer dissolved in the original nonpolar solvent toluene, but the quantum dot material in the non-illumination region is still dissolved in the nonpolar solvent, such as toluene. Therefore, if the patterned quantum dot film is developed with toluene, the quantum dot material in the non-illumination region is washed away, leaving the quantum dot material in the illumination region to realize negative photoresist patterning.

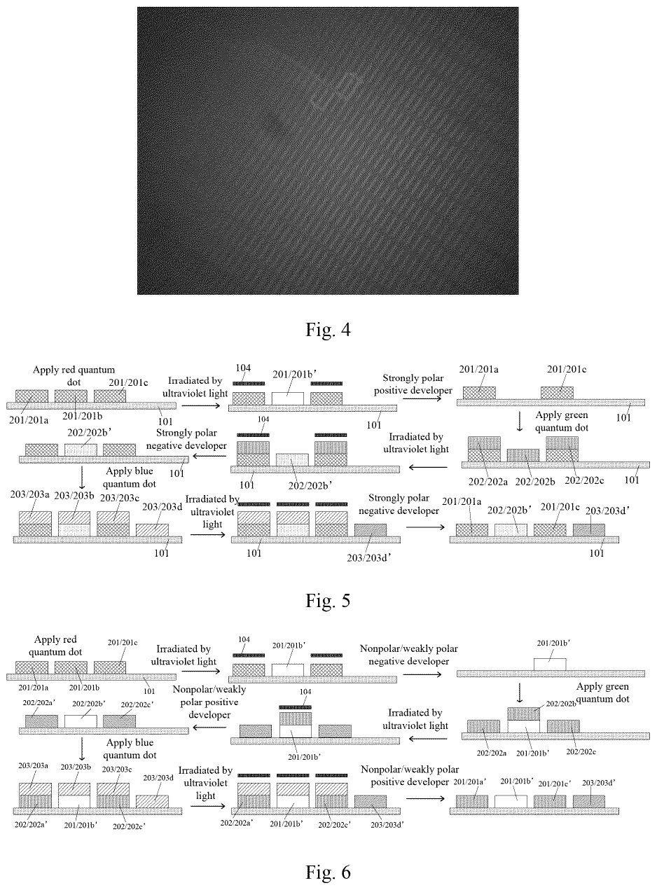

For example, in a comparative example of the fourth embodiment, before the quantum dot film is irradiated by ultraviolet light or infrared light, the first quantum dot ligand on the surface of the quantum dot body is nonpolar or weakly polar, the photosensitizer is weakly polar, and the developer is nonpolar or weakly polar. This combination cannot realize patterning the quantum dot film to form a quantum dot film. For example, the components of the quantum dot composition include red quantum dot body CdSe/ZnS, the first quantum dot ligand on the surface of the red quantum dot body is a nonpolar ligand of oleic acid, the photosensitizer is a weakly polar organic molecule of 2,3,4,5-tetrafluoro-4-azido benzaldehyde, and the solvent is nonpolar solvent toluene. Spin coating the quantum dot composition on a substrate to form a quantum dot film, the mass and volume concentrations of the quantum dot material and the photosensitizer are 25 g/L and 0.5 g/L, respectively. The quantum dot film is shielded by a mask plate, and a partial region of the quantum dot film is irradiated by ultraviolet light, that is, the partial region is exposed by ultraviolet light for 20 seconds, and is immersed and developed in toluene. For example, FIG. 4 is a fluorescence microscope picture of a quantum dot film formed by the patterning method of the quantum dot film provided by the comparative example of the fourth embodiment. It can be seen from FIG. 4 that there is no red pattern after development, because the photosensitizer is connected to the ligand oleic acid on the surface of the quantum dot body after ultraviolet illumination, but the polarity of the ligand on the surface of the quantum dot body does not change obviously before and after ultraviolet illumination. Quantum dot materials in the illumination region and the non-illumination region are still dissolved in the original nonpolar solvent toluene, and are finally developed by toluene, leaving no patterns in the illumination region and non-illumination region.

For example, in the comparative example of the fourth embodiment, because the photosensitizer 2,3,4,5-tetrafluoro-4-azido benzaldehyde is connected to the first quantum dot ligand oleic acid on the surface of the quantum dot body during the ultraviolet exposure to form the second quantum dot ligand, and because the photosensitizer contained the aldehyde group with weak polarity, the polarity of the ligand on the surface of the quantum dot body remains basically unchanged after the ultraviolet exposure, that is, the ligand on the surface of the quantum dot body in the illumination region is still weak polarity. Therefore, if the patterned quantum dot film is developed with toluene, the quantum dot materials in the illumination region and the non-illumination region are still dissolved in the original nonpolar solvent toluene, and are finally developed by toluene, and no patterns can be left in the illumination region and the non-illumination region.

For example, in other examples, from the perspective of not affecting the electroluminescent performance of the quantum dots, the second embodiment and the fourth embodiment of negative photoresist patterning have special requirements for the photosensitizer. In order to minimize the influence of patterning process on the electrical properties of the finally formed devices, the photosensitizer can be selected to have high sensitivity and long wavelength response.

For example, in another example, in order to form a full-color pattern, and because the polarities of red quantum dots, green quantum dots and blue quantum dots are different, from the perspective of film retention rate, the polarities of corresponding photosensitizers are different when forming the patterned red quantum dot film, the patterned green quantum dot film and the patterned blue quantum dot film.

For example, the following description takes a full-color pattern including patterned red quantum dot film, a patterned green quantum dot film and a patterned blue quantum dot film as an example.

For example, FIG. 5 is a process diagram for forming a full-color pattern provided by at least one embodiment of the present disclosure. As illustrated by FIG. 5, a nonpolar or weakly polar red quantum dot film 201 is formed by applying a red quantum dot composition on a substrate 101, and the nonpolar or weakly polar red quantum dot film 201 includes a nonpolar or weakly polar red quantum dot block 201b in the middle position, and nonpolar or weakly polar red quantum dot blocks 201a and 201c located at the left side and the right side of the nonpolar or weakly polar red quantum dot block 201b, respectively, and then a mask plate 104 is used to shield a partial region of the nonpolar or weakly polar red quantum dot film 201, for example, the nonpolar or weakly polar red quantum dot blocks 201a and 201c on the left side and the right side are shielded, and ultraviolet light is used for illumination, so that ultraviolet light is incident on the nonpolar or weakly polar red quantum dot block 201b located in the middle position, so that the first quantum dot ligand on the quantum dot body included in the nonpolar or weakly polar red quantum dot block 201b in the middle position reacts with the photosensitizer to form a second quantum dot ligand, the nonpolar or weakly polar red quantum dot block 201b forms a strongly polar red quantum dot block 201b′. The first quantum dot ligand is nonpolar or weakly polar, and the second quantum dot ligand is strongly polar. That is, the photosensitizer in the red quantum dot composition includes a strongly polar group, and the first quantum dot ligand includes a nonpolar or weakly polar group, so that the exposed red quantum dot block 201b′ is easily soluble in the strongly polar solvent, while the red quantum dot blocks 201a and 201c in the unexposed region are still nonpolar or weakly polar, and are not easily soluble in the strongly polar solvent, so that the red quantum dot block 201b′ in the middle position can be removed by using a strongly polar positive developer to obtain a red quantum dot film.

Then, a green quantum dot composition is applied on the red quantum dot film to form a strongly polar green quantum dot film 202, which includes a strongly polar green quantum dot block 202b located in the middle position and strongly polar green quantum dot blocks 202a and 202c located at the left side and the right side of the strongly polar green quantum dot block 202b, then, a mask plate 104 is used to shield a partial region of the strong polarity green quantum dot film 202, for example, the strong polarity green quantum dot blocks 202a and 202c on the left side and the right side, and ultraviolet light is used for illumination, so that the ultraviolet light is incident on the strong polarity green quantum dot block 202b located in the middle position. In this way, the first quantum dot ligand on the quantum dot body included in the strongly polar green quantum dot block 202b in the middle position reacts with the photosensitizer to form a second quantum dot ligand, the first quantum dot ligand is strongly polar and the second quantum dot ligand is nonpolar or weakly polar, that is, the photosensitizer in the green quantum dot composition includes a nonpolar or weakly polar group, and the first quantum dot ligand includes a strongly polar group. In this way, the exposed green quantum dot block 202a′ is easily soluble in the nonpolar or weakly polar solvent, while the green quantum dot blocks 202a and 202c in the unexposed regions are still strongly polar and not easily soluble in the nonpolar or weakly polar solvent, so that the strongly polar green quantum dot blocks 202a and 202c located at the left side and the right side can be removed by using a strongly polar negative developer, and the green quantum dot blocks 202b′ located in the middle position can be retained to obtain a green quantum dot film.

Finally, a blue quantum dot composition is applied on the red quantum dot film and the green quantum dot film to form a blue quantum dot film 203 with strong polarity, which includes blue quantum dot blocks 203a, 203b and 203c with strong polarity arranged on the red quantum dot block 201a, the green quantum dot block 202b′ and the red quantum dot block 201c in sequence, and a strongly polar blue quantum dot block 203d located at the right side of the red quantum dot block 201c, then a mask plate 104 is used to shield a partial region of the strongly polar blue quantum dot film 203, for example, the strongly polar blue quantum dot blocks 203a, 203b and 203c on the red quantum dot block 201a, the green quantum dot block 202b′ and the red quantum dot block 201c are shielded, and ultraviolet light is used for illumination, so that ultraviolet light is incident on the strongly polar blue quantum dot block 203d located on the right side of the red quantum dot block 201c, so that the first quantum dot ligand on the quantum dot body included in the strongly polar blue quantum dot block 203d located on the right side of the red quantum dot block 201c reacts with the photosensitizer to form a second quantum dot ligand, the first quantum dot ligand is strongly polar, and the second quantum dot ligand is nonpolar or weakly polar, that is, the photosensitizer in the blue quantum dot composition includes a nonpolar or weakly polar group, and the first quantum dot ligand includes a strongly polar group, so that the exposed blue quantum dot block 203d′ is easily soluble in the nonpolar or weakly polar solvent, while the unexposed blue quantum dot blocks 203a, 203b and 203c are still strongly polar and not easily soluble in nonpolar or weakly polar solvents. Therefore, the nonpolar or weakly polar positive developer can be used to remove the blue quantum dot blocks 203a, 203b and 203c in the unexposed regions, and the blue quantum dot block 203d′ located on the right side of the red quantum dot block 201c can be retained to obtain the blue quantum dot film.

For example, FIG. 6 is another process diagram for forming another full-color pattern provided by at least one embodiment of the present disclosure. As illustrated by FIG. 6, a nonpolar or weakly polar red quantum dot film 201 is formed by applying a red quantum dot composition on a substrate 101, and the nonpolar or weakly polar red quantum dot film 201 includes a nonpolar or weakly polar red quantum dot block 201b in the middle position, and nonpolar or weakly polar red quantum dot blocks 201a and 201c located at the left side and the right side of the nonpolar or weakly polar red quantum dot block 201b respectively, and then a mask plate 104 is used to shield a partial region of the nonpolar or weakly polar red quantum dot film 201, for example, the nonpolar or weakly polar red quantum dot blocks 201a and 201c on the left side and the right side are shielded, and ultraviolet light is used for illumination, so that ultraviolet light is incident on the nonpolar or weakly polar red quantum dot block 201b located in the middle position, so that the first quantum dot ligand on the quantum dot body included in the nonpolar or weakly polar red quantum dot block 201b in the middle position reacts with the photosensitizer to form a second quantum dot ligand, the nonpolar or weakly polar red quantum dot block 201b forms a strongly polar red quantum dot block 201b′. That is, the photosensitizer in the red quantum dot composition includes a strongly polar group, and the first quantum dot ligand includes a nonpolar or weakly polar group, so that the exposed red quantum dot block 201b′ is easily soluble in the strongly polar solvent, while the red quantum dot blocks 201a and 201c in the unexposed region are still nonpolar or weakly polar and not easily soluble in the strongly polar solvent, so that the nonpolar or weakly polar red quantum dot blocks 201a and 201c located at the left side and the right side can be removed by using the nonpolar or weakly polar negative developer, so as to obtain a red quantum dot film.

Then, a green quantum dot composition is applied on the red quantum dot film to form a nonpolar or weakly polar green quantum dot film 202, which includes a nonpolar or weakly polar green quantum dot block 202b located in the middle and nonpolar or weakly polar green quantum dot blocks 202a and 202c located at the left side and the right side of the nonpolar or weakly polar green quantum dot block 202b, respectively. Then, a mask plate 104 is used to shield a partial region of the nonpolar or weakly polar green quantum dot film 202, for example, the nonpolar or weakly polar green quantum dot block 202b located in the middle position is shielded, and ultraviolet light is used for illumination, so that the ultraviolet light is incident on the nonpolar or weakly polar green quantum dot blocks 202a and 202c located at the left side and the right side of the nonpolar or weakly polar green quantum dot block 202b, respectively. In this way, the first quantum dot ligands on the quantum dot bodies included in the nonpolar or weakly polar green quantum dot blocks 202a and 202c at the left side and the right side react with the photosensitizer to form a second quantum dot ligand, the first quantum dot ligand is nonpolar or weakly polar and the second quantum dot ligand is strongly polar, that is, the photosensitizer in the green quantum dot composition includes a strongly polar group, and the first quantum dot ligand includes a nonpolar or weakly polar group. In this way, the exposed green quantum dot blocks 202a′ and 202c′ are easily soluble in strongly polar solvents, while the green quantum dot blocks 202a′ and 202c′ in unexposed regions are still nonpolar or weakly polar, and are not easily soluble in the strongly polar solvent, so that the nonpolar or weakly polar green quantum dot block 202b in the middle position can be removed by using nonpolar or weakly polar positive developer, and the strongly polar green quantum dot blocks 202a′ and 202c′ on the left side and the right side can be left, so as to obtain a green quantum dot film.

Finally, a blue quantum dot composition is applied on the red quantum dot film and the green quantum dot film to form a nonpolar or weakly polar blue quantum dot film 203, which includes nonpolar or weakly polar blue quantum dot blocks 203a, 203b, 203c sequentially arranged on the green quantum dot block 202a′, the red quantum dot block 201b′ and the green quantum dot block 202c′, and a nonpolar or weakly polar blue quantum dot block 203d located on the right side of the green quantum dot block 202c′, and then a mask plate 104 is used to shield a partial region of the nonpolar or weakly polar blue quantum dot film 203, for example, the nonpolar or weakly polar blue quantum dot blocks 203a, 203b and 203c on the green quantum dot block 202a′, the red quantum dot block 201b′ and the green quantum dot block 202c′ are shielded. Ultraviolet light is irradiated to make the ultraviolet light incident on the nonpolar or weakly polar blue quantum dot block 203d located on the right side of the green quantum dot block 202c′, so that the first quantum dot ligand on the quantum dot body included in the nonpolar or weakly polar blue quantum dot block 203d located on the right side of the green quantum dot block 202c′ reacts with the photosensitizer to form a second quantum dot ligand, and the first quantum dot ligand is nonpolar or weakly polar, the second quantum dot ligand is strongly polar, that is, the photosensitizer in the blue quantum dot composition includes a strongly polar group, and the first quantum dot ligand includes a nonpolar or weakly polar group, so that the exposed blue quantum dot block 203d′ is easily soluble in strongly polar solvents, while the blue quantum dot blocks 203a, 203b and 203c in the unexposed region are still nonpolar or weakly polar and easily soluble in nonpolar or weakly polar solvent. Therefore, the nonpolar or weakly polar positive developer can be used to remove the blue quantum dot blocks 203a, 203b and 203c in the unexposed region, and the blue quantum dot block 203d′ located on the right side of the green quantum dot block 202c′ can be retained to obtain a blue quantum dot film.

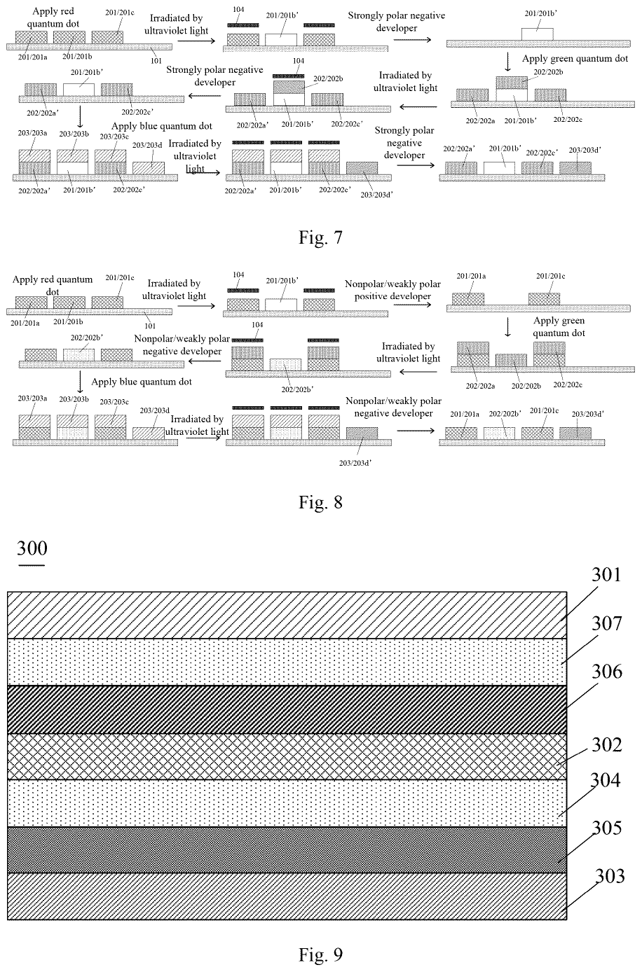

For example, FIG. 7 is another process diagram of forming still another full-color pattern provided by at least one embodiment of the present disclosure. As illustrated by FIG. 7, a strongly polar red quantum dot film 201 is formed by applying a red quantum dot composition on a substrate 101, and the strongly polar red quantum dot film 201 includes a strongly polar red quantum dot block 201b in the middle position, and strongly polar red quantum dot blocks 201a and 201c located at the left side and the right side of the strongly polar red quantum dot block 201b, respectively. Then, a mask plate 104 is used to shield a partial region of the strongly polar red quantum dot film 201, for example, the strongly polar red quantum dot blocks 201a and 201c at the left side and the right side are shielded, and ultraviolet light is used for illumination, so that the ultraviolet light is incident on the strongly polar red quantum dot block 201b located in the middle position. In this way, the first quantum dot ligand on the quantum dot body included in the strongly polar red quantum dot block 201b in the middle position reacts with the photosensitizer to form a second quantum dot ligand, the strongly polar red quantum dot block 201b forms nonpolar or weakly polar red quantum dot block 201b′, and the first quantum dot ligand is strongly polar and the second quantum dot ligand is nonpolar or weakly polar, that is, the photosensitizer in the red quantum dot composition includes a nonpolar or weakly polar group, and the first quantum dot ligand includes a strongly polar group, so that the exposed red quantum dot blocks 201b′ are easily soluble in nonpolar or weakly polar solvents, while the red quantum dot blocks 201a and 201c in the unexposed regions are still strongly polar and not easily soluble in the nonpolar or weakly polar solvent, so that the strongly polar red quantum dot blocks 201a and 201c at the left side and the right side can be removed by using a strongly polar negative developer to obtain a red quantum dot film.

Then, a green quantum dot composition is applied on the red quantum dot film to form a strong polarity green quantum dot film 202, which includes a strong polarity green quantum dot block 202b located in the middle position and strong polarity green quantum dot blocks 202a and 202c located at the left side and the right side of the strong polarity green quantum dot block 202b, respectively. Then, a mask plate 104 is used to shield a partial region of the strong polarity green quantum dot film 202, for example, the strong polarity green quantum dot block 202b located in the middle position is shielded, and ultraviolet light is used for illumination, so that the ultraviolet light is incident on the strong polarity green quantum dot blocks 202a and 202c located at the left side and the right side of the strong polarity green quantum dot block 202b, respectively. In this way, the first quantum dot ligand on the quantum dot body included in the strongly polar green quantum dot blocks 202a and 202c on the left side and the right side react with the photosensitizer to form a second quantum dot ligand, the first quantum dot ligand is strongly polar, and the second quantum dot ligand is nonpolar or weakly polar, that is, the photosensitizer in the green quantum dot composition includes a nonpolar or weakly polar group, and the first quantum dot ligand includes a strongly polar group. In this way, the exposed green quantum dot blocks 202a′ and 202c′ are easily soluble in nonpolar or weakly polar solvent, while the green quantum dot blocks 202a′ and 202c′ in the unexposed regions are still strongly polar and not easily soluble in nonpolar or weakly polar solvent, so that the strongly polar green quantum dot blocks 202b located in the middle position can be removed by using a strongly polar negative developer, and the nonpolar or weakly polar green quantum dot blocks 202a′ and 202c′ located at the left side and the right side can be left, to obtain a green quantum dot film.

Finally, a blue quantum dot composition is applied on the red quantum dot film and the green quantum dot film to form a strongly polar blue quantum dot film 203, which includes strongly polar blue quantum dot blocks 203a, 203b and 203c which are sequentially arranged on the green quantum dot block 202a′, the red quantum dot block 201b′ and the green quantum dot block 202c′, and a strongly polar blue quantum dot block 203d located on the right side of the green quantum dot block 202c′, then a mask plate 104 is used to shield a partial region of the strongly polar blue quantum dot film 203, for example, strongly polar blue quantum dot blocks 203a, 203b and 203c on the green quantum dot block 202a′, the red quantum dot block 201b′ and the green quantum dot block 202c′ are shielded, and ultraviolet light is used for illumination, so that ultraviolet light is incident on the strongly polar blue quantum dot block 203d located on the right side of the green quantum dot block 202c′, so that a first quantum dot ligand on the quantum dot body included in the strongly polar blue quantum dot block 203d located on the right side of the green quantum dot block 202c′ reacts with a photosensitizer to form a second quantum dot ligand, the first quantum dot ligand is strongly polar, and the second quantum dot ligand is nonpolar or weakly polar, that is, the photosensitizer in the blue quantum dot composition includes a nonpolar or weakly polar group, and the first quantum dot ligand includes a strongly polar group, so that the exposed blue quantum dot block 203d′ is easily soluble in the nonpolar or weakly polar solvent, while the unexposed blue quantum dot blocks 203a, 203b and 203c are still strongly polar and easily soluble in strongly polar solvent. Therefore, the blue quantum dot blocks 203a, 203b and 203c in the unexposed region can be removed by using a strong polarity negative developer, and the blue quantum dot block 203d′ located on the right side of the green quantum dot block 202c′ is retained to obtain a blue quantum dot film.

For example, FIG. 8 is another process diagram of forming still another full-color pattern provided by at least one embodiment of the present disclosure. As illustrated by FIG. 8, a strongly polar red quantum dot film 201 is formed by applying a red quantum dot composition on a substrate 101, and the strongly polar red quantum dot film 201 includes a strongly polar red quantum dot block 201b in the middle position, and strongly polar red quantum dot blocks 201a and 201c located at the left side and the right side of the strongly polar red quantum dot block 201b, respectively. Then, a mask plate 104 is used to shield a partial region of the strongly polar red quantum dot film 201, for example, the strongly polar red quantum dot blocks 201a and 201c on the left side and the right side are shielded, and ultraviolet light is used for illumination, so that the ultraviolet light is incident on the strongly polar red quantum dot block 201b located in the middle position. In this way, the first quantum dot ligand on the quantum dot body included in the strongly polar red quantum dot block 201b in the middle position reacts with the photosensitizer to form a second quantum dot ligand, the strongly polar red quantum dot block 201b forms a nonpolar or weakly polar red quantum dot block 201b′, and the first quantum dot ligand is strongly polar and the second quantum dot ligand is nonpolar or weakly polar, that is, the photosensitizer in the red quantum dot composition includes a nonpolar or weakly polar group, and the first quantum dot ligand includes a strongly polar group, so that the exposed red quantum dot blocks 201b′ are easily soluble in nonpolar or weakly polar solvent, while the red quantum dot blocks 201a and 201c in the unexposed regions are still strongly polar and not easily soluble in nonpolar or weakly polar solvent, so that the strongly polar red quantum dot blocks 201a and 201c on the left side and the right side can be removed by using a strongly polar negative developer to obtain a red quantum dot film.

Then, a green quantum dot composition is applied on the red quantum dot film to form a strongly polar green quantum dot film 202, which includes a strongly polar green quantum dot block 202b located in the middle position and strongly polar green quantum dot blocks 202a and 202c located at the left side and the right side of the strongly polar green quantum dot block 202b, then, a mask plate 104 is used to shield a partial region of the strong polarity green quantum dot film 202, for example, the strong polarity green quantum dot block 202b located in the middle position is shielded, and ultraviolet light is used for illumination, so that the ultraviolet light is incident on the strong polarity green quantum dot blocks 202a and 202c located at the left side and the right side. In this way, the first quantum dot ligands on the quantum dot bodies included in the strongly polar green quantum dot blocks 202a and 202c on the left side and the right side react with the photosensitizer to form a second quantum dot ligand, the first quantum dot ligand is strongly polar and the second quantum dot ligand is nonpolar or weakly polar, that is, the photosensitizer in the green quantum dot composition includes a nonpolar or weakly polar group, and the first quantum dot ligand includes a strongly polar group. In this way, the exposed green quantum dot blocks 202a′ and 202c′ are easily soluble in nonpolar or weakly polar solvent, while the unexposed green quantum dot blocks 202a′ and 202c′ are still strongly polar and not easily soluble in nonpolar or weakly polar solvent, so that the strongly polar green quantum dot blocks 202b located in the middle position can be removed by using a strongly polar negative developer, and the green quantum dot blocks 202a′ and 202c′ located at the left side and the right side are left, so as to obtain a green quantum dot film.

Finally, a blue quantum dot composition is applied on the red quantum dot film and the green quantum dot film to form a strongly polar blue quantum dot film 203, which includes strongly polar blue quantum dot blocks 203a, 203b and 203c which are sequentially arranged on the green quantum dot block 202a′, the red quantum dot block 201b′ and the green quantum dot block 202c′, and a strongly polar blue quantum dot block 203d located on the right side of the green quantum dot block 202c″, and then a mask plate 104 is used to shield a partial region of the strongly polar blue quantum dot film 203, for example, strongly polar blue quantum dot blocks 203a, 203b and 203c on the green quantum dot block 202a′, the red quantum dot block 201b′ and the green quantum dot block 202c′ are shielded, and ultraviolet light is used for illumination, so that ultraviolet light is incident on the strongly polar blue quantum dot block 203d located on the right side of the green quantum dot block 202c′, so that a first quantum dot ligand on the quantum dot body included in the strongly polar blue quantum dot block 203d located on the right side of the green quantum dot block 202c′ reacts with a photosensitizer to form a second quantum dot ligand, the first quantum dot ligand is strongly polar, and the second quantum dot ligand is nonpolar or weakly polar, That is, the photosensitizer in the blue quantum dot composition includes a nonpolar or weakly polar group, and the first quantum dot ligand includes a strongly polar group, so that the exposed blue quantum dot block 203d′ is easily soluble in the nonpolar or weakly polar solvent, while the unexposed blue quantum dot blocks 203a, 203b and 203c are still strongly polar and not easily soluble in nonpolar or weakly polar solvent. Therefore, the blue quantum dot blocks 203a, 203b and 203c in the unexposed regions can be removed by using a strong polarity negative developer, and the blue quantum dot block 203d′ located on the right side of the green quantum dot block 202c′ can be retained to obtain a blue quantum dot film.

For example, the process of forming a full-color pattern can also be other solutions other than the above-mentioned process diagrams shown in FIG. 5 to FIG. 8, and patterns with arbitrary color combinations can be obtained by adjusting the shielding position and the exposure position of the mask plate, which is not limited by the embodiment of the present disclosure.

At least one embodiment of the present disclosure also provides a quantum dot display device, which includes a quantum dot film prepared by using the quantum dot composition in any one of the above embodiments, and other layer structures included in the quantum dot display device can refer to the conventional design, which is not limited by the embodiments of the present disclosure.

For example, in the quantum dot display device provided by the embodiment of the present disclosure, the polarity of the first quantum dot ligand of the quantum dot can be changed after being connected with the second functional group in the photosensitizer through hydrocarbon insertion reaction or carbon-carbon double bond addition reaction, so as to achieve the purpose of subsequent photolithography patterning of the quantum dot film, and at the same time, the molecular weight of the second quantum dot ligand can be made larger than that of the first quantum dot ligand. In the process of preparing the patterned quantum dot film, the polarity of the ligand on the surface of the quantum dot body in the quantum dot material in the illumination region is changed by shielding the mask plate on the quantum dot film and using ultraviolet light to irradiate a partial region of the quantum dot film, so that the polarity of the ligand on the surface of quantum dot body in the ultraviolet light irradiated region of the quantum dot film is different from that in the region which is not irradiated by the ultraviolet light of the quantum dot film. Besides, the original environment of the first quantum dot ligand of the quantum dot body can also be basically kept, so that the influence on the performance of the finally formed electroluminescent device is very small, that is, the coordination groups included in the first quantum dot ligand are not changed, so that the interaction between the first quantum dot ligand and the quantum dot body is not affected, and the phenomenon that the first quantum dot ligand falls off from the surface of the quantum dot body is not caused, so that defects are not introduced, so that the pattern of the quantum dot film can be completed by selecting a good solvent of a suitable quantum dot material according to the pattern of the quantum dot film to be formed. For example, the quantum dot material in the region irradiated by light remains, and the quantum dot material in the region not irradiated by light is washed away, or the quantum dot material in the region not irradiated by light remains, and the quantum dot material in the region irradiated by light is washed away. In this way, a simple and efficient patterning method of the quantum dot film can be provided, and the damage to the photoelectric properties of the quantum dots caused by the introduction of photoresist can be avoided.

For example, FIG. 9 is a schematic cross-sectional structure of a quantum dot display device provided by at least one embodiment of the present disclosure. As illustrated by FIG. 9, the quantum dot display device is a quantum dot light emitting device 300, which includes a first electrode 301, a second electrode 303 and a quantum dot film 302 sandwiched between the first electrode 301 and the second electrode 303.

For example, in the structure shown in FIG. 9, the first electrode 301 may be a cathode and the second electrode 303 may be an anode; alternatively, the first electrode 301 may be an anode and the second electrode 303 may be a cathode. And in the structure shown in FIG. 9, the light emitting principle of the quantum dot film in the quantum dot light emitting device is electroluminescence.

For example, as illustrated by FIG. 9, the quantum dot light emitting device 300 may further include a hole transport layer 304, a hole injection layer 305, an electron transport layer 306 and an electron injection layer 307. The quantum dot light emitting device 300 may have an upright structure or an inverted structure. FIG. 8 illustrates an upright structure as an example. For example, in an upright structure, the quantum dot light emitting device includes a second electrode 303, a hole injection layer 305, a hole transport layer 304, a quantum dot film 302, an electron transport layer 306, an electron injection layer 307 and a first electrode 301 which are sequentially stacked on a substrate, the first electrode 301 is a cathode and the second electrode 303 is an anode. In the inverted structure, the quantum dot light emitting device includes a first electrode 301, an electron injection layer, an electron transport layer, a quantum dot film 302, a hole transport layer, a hole injection layer and a second electrode 303 which are sequentially stacked on a substrate, the first electrode 301 is a cathode and the second electrode 303 is an anode.

For example, a material of the hole transport layer 304 includes at least one selected from the group consisting of N,N′-bis(1-naphthyl)-N,N′-diphenyl-1,1′-biphenyl-4,4′-diamine (NPB), 4,4′,4″-tris[N-(3-methylphenyl)-N-phenylamino]triphenylamine (m-MTDATA) and 4,4′-bis[N-(4-carbazolylphenyl)-N-phenylamino]biphenyl (CPB), but is not limited thereto.

For example, the hole injection layer 305 can adopt a metal oxide MeO, such as MoO₃, or it can also adopt a p-type doped MeO (metal oxide)-TPD (N,N′-bis(3-methylphenyl)-N,N′-diphenyl-1,1′-biphenyl-4,4′-diamine):F4TCNQ (N,N,N′,N′-tetramethoxyphenyl-p-phenylenediamine:2,3,5,6-tetrafluoro-7,7′,8,8′-tetracyanoquinodimethane) or m-MTDATA:F4TCNQ (4,4′,4″-tris(N-3-methylphenyl-N-phenylamino)triphenylamine: 2,3,5,6-tetrafluoro-7,7′,8,8′-tetracyanoquinodimethane), etc.

For example, a material of the second electrode 303 can be a transparent conductive material including indium tin oxide (ITO), indium zinc oxide (IZO), indium gallium oxide (IGO), gallium zinc oxide (GZO), zinc oxide (ZnO), indium oxide (In₂O₃), zinc aluminum oxide (AZO), carbon nanotubes, etc., and the second electrode 303 is an anode.

For example, a material of the first electrode 301 includes magnesium, aluminum, lithium single metal or magnesium aluminum alloy (MgAl), lithium aluminum alloy (LiAl) and the like, and the first electrode 301 is a cathode.

For example, the material of the electron injection layer 307 includes at least one selected from the group consisting of lithium oxide (Li₂O), cesium oxide (Cs₂O), sodium oxide (Na₂O), lithium carbonate (Li₂CO₃), cesium carbonate (Cs₂CO₃), or sodium carbonate (Na₂CO₃), lithium fluoride (LiF), cesium fluoride (CsF), sodium fluoride (NaF) and calcium fluoride (CaF₂), aluminum tris(8-hydroxyquinoline) (Alq3), lithium 8-hydroxyquinolate (Liq), gallium 8-hydroxyquinolate, bis[2-(2-hydroxyphenyl)-1-pyridinato]beryllium, and 2-(4-diphenyl)-5-(4-tert-butylphenyl)-1,3,4-oxadiazole (PBD).

For example, in an example, a material of the electron transport layer 306 includes at least one selected from the group consisting of zinc oxide, zinc oxide doped with magnesium ions and zinc oxide doped with cesium ions.

For example, in an example, a material of the electron transport layer 306 includes at least one selected from the group consisting of 4,7-diphenyl-1,10-phenanthroline (BPhen), 1,3,5-tris(1-phenyl-1H-benzimidazol-2-yl)benzene (TPBI) and n-type doping electron transport material, which is not limited to this. The n-type doping electron transport material includes, for example, 2,9-dimethyl-4,7-diphenyl-1,10-phenanthroline (BCP):Li₂CO₃, aluminum tris(8-hydroxyquinoline) (Alq₃):Mg, TPBI:Li, etc., but the embodiments of the present disclosure are not limited thereto.

It should be noted that, the materials and the structures of the above-mentioned first electrode 301 and second electrode 303 are only an example in the embodiment of the present disclosure. The first electrode and the second electrode can also be made of other materials. The quantum dot light emitting device can be divided into a single-sided light emitting quantum dot device and a double-sided light emitting quantum dot device according to the different materials of the first electrode and the second electrode. In a case that the material of one of the anode and the cathode is opaque or semi-transparent, the quantum dot light emitting device is a single-sided light emitting quantum dot device, and in a case that the material of the anode and the cathode are both transparent and/or semi-transparent, the quantum dot light emitting device is a double-sided light emitting quantum dot device.

According to requirements, the materials of the first electrode and the second electrode can be selected to be suitable for a top light emission type, a bottom light emission type and a double-sided light emission type respectively, and the embodiment of the present disclosure does not limit the selection of the materials of the first electrode and the second electrode.

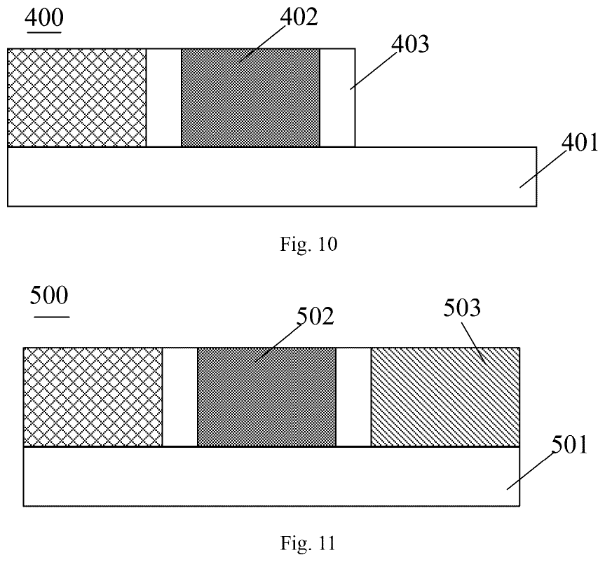

For example, FIG. 10 is a schematic cross-sectional structure of another quantum dot display device provided by at least one embodiment of the present disclosure. As illustrated by FIG. 10, the quantum dot display device is a quantum dot color conversion device 400, which includes a light emitting substrate 401 and a quantum dot film 402 located on the light emitting substrate 401. For example, the light emitting principle of the quantum dot film in the quantum dot color conversion device is photoluminescence.

For example, in the structure shown in FIG. 10, the light emitting substrate 401 is a blue OLED light emitting substrate.

For example, a pixel definition layer 403 is arranged on a blue OLED light emitting substrate, and then a red quantum dot film and a green quantum dot film are sequentially formed in the openings defined by the pixel definition layer 403. Because the blue OLED light emitting substrate itself can emit blue light, the blue light can excite the red quantum dot film to emit red light, and the blue light can also excite the green quantum dot film to emit green light, thus a full-color quantum dot display device is obtained. The embodiment of the present disclosure does not limit the specific structure of the above-mentioned blue OLED light emitting substrate, but can be determined according to the actual situation.

For example, in the structure shown in FIG. 10, the light emitting substrate 401 may be a Micro LED (Micro Light Emitting Diode) light emitting substrate, and the light emitting color of the micro LED light emitting substrate 401 may be blue. By arranging a red quantum dot film and a green quantum dot film on the light emitting unit of the blue Micro LED light emitting substrate 401, a full-color quantum dot display device based on Micro LED technology can also be obtained. The embodiment of the present disclosure is not limited to the specific structure of the blue Micro LED light emitting substrate 401, but can be determined according to the actual situation.

For example, FIG. 11 is a schematic cross-sectional structure of another quantum dot display device provided by at least one embodiment of the present disclosure. As illustrated by FIG. 11, the quantum dot display device is a quantum dot color conversion device 500, which includes a light emitting substrate 501 and a quantum dot film 502 located on the light emitting substrate 501. For example, the light emitting principle of the quantum dot film in the quantum dot color conversion device is photoluminescence.

For example, in the structure shown in FIG. 11, the light emitting substrate 501 is a white OLED light emitting substrate.

For example, a pixel definition layer 503 is arranged on a white OLED light emitting substrate, and then a red quantum dot film, a green quantum dot film and a blue quantum dot film are sequentially formed in the opening defined by the pixel definition layer 503. White light can excite the red quantum dot film to emit red light, the green quantum dot film to emit green light and the blue quantum dot film to emit blue light, so as to obtain a full-color quantum dot display device. The embodiment of the present disclosure does not limit the specific structure of the white OLED light emitting substrate, but can be determined according to the actual situation.

Based on the same inventive concept, an embodiment of the present disclosure also provides a display device, which includes the quantum dot light emitting device provided in any one of the above embodiments. For example, in specific implementation, the display device provided by the embodiment of the present invention can be any product or component with a display function, such as a mobile phone, a tablet computer, a television, a display, a notebook computer, a digital photo frame, a navigator, etc. Other essential components of the display device should be understood by those skilled in the art, and will not be repeated here, nor should they be taken as limitations of the present invention. For the implementation of the display device, please refer to the above-mentioned embodiments of quantum dot light emitting devices, and the repetition will not be described here.

The following points need to be explained:

(1) The drawings of the embodiment of this disclosure only relate to the structure related to the embodiment of this disclosure, and other structures can refer to the general design.

(2) For the sake of clarity, in the drawings used to describe the embodiments of the present disclosure, the thickness of layers or regions is enlarged or reduced, that is, these drawings are not drawn to actual scale.

(3) In the case of no conflict, the embodiments of the present disclosure and the features in the embodiments can be combined with each other to obtain a new embodiment.

The above is only the specific implementation of the present disclosure, but the protection scope of this disclosure is not limited to this. Any person familiar with this technical field can easily think of changes or substitutions within the technical scope disclosed in the present disclosure, which should be included in the protection scope of the present disclosure. Therefore, the scope of protection of this disclosure should be based on the scope of protection of the claims.

1. A quantum dot composition, comprising:
a quantum dot material and a photosensitizer which are mixed,
wherein the quantum dot material comprises a quantum dot body and a first quantum dot ligand on a surface of the quantum dot body;
the photosensitizer is configured to react with the first quantum dot ligand under illumination to form a second quantum dot ligand, a molecular weight of the second quantum dot ligand is greater than a molecular weight of the first quantum dot ligand, and a polarity of the second quantum dot ligand is different from a polarity of the first quantum dot ligand.

2. The quantum dot composition according to claim 1, wherein a polarity index of the second quantum dot ligand is greater than or equal to 0 and less than 3.6, and correspondingly, a polarity index of the first quantum dot ligand is greater than 3.6 and less than 13; or, the polarity index of the first quantum dot ligand is greater than or equal to 0 and less than 3.6, and correspondingly, the polarity index of the second quantum dot ligand is greater than 3.6 and less than 13.

3. The quantum dot composition according to claim 1, wherein,
the first quantum dot ligand comprises a coordination group combined with the surface of the quantum dot body, a first connection group connected with the coordination group, and a first functional group connected with the first connection group;
the photosensitizer comprises a photosensitive group, a second connection group connected with the photosensitive group, and a second functional group connected with the second connection group;
the first functional group and the second functional group have different polarities.

4. The quantum dot composition according to claim 3, wherein the first quantum dot ligand comprises a C—H bond, and the photosensitive group is configured to undergo a hydrocarbon insertion reaction with the C—H bond comprised in the first quantum dot ligand under illumination to form the second quantum dot ligand.

5. The quantum dot composition according to claim 4, wherein the photosensitive group forms at least one selected from the group consisting of nitrogen carbene, carbonyl radical and carbene under illumination, and at least one of the nitrogen carbene, the carbonyl radical and the carbene undergoes a hydrocarbon insertion reaction with the C—H bond comprised in the first quantum dot ligand to form the second quantum dot ligand.

6. The quantum dot composition according to claim 4, wherein the photosensitive group comprises at least one selected from the group consisting of azide, benzophenone and diazirine.

7. The quantum dot composition according to claim 3, wherein the quantum dot ligand comprises a C═C bond, and the photosensitive group is configured to undergo an addition reaction with the C═C bond comprised in the first quantum dot ligand under illumination to form the second quantum dot ligand.

8. The quantum dot composition according to claim 7, wherein the photosensitive group forms a nitrogen carbene under illumination, and the nitrogen carbene undergoes an addition reaction with the C═C bond comprised in the first quantum dot ligand to form the second quantum dot ligand.

9. The quantum dot composition according to claim 7, wherein the photosensitive group comprises azide.

10. The quantum dot composition according to claim 2, wherein,
the coordination group comprises at least one selected from the group consisting of sulfhydryl, carboxyl, amino, phosphine and phosphine oxide;
the first connection group comprises at least one selected from the group consisting of C1-C30 linear alkyl, unsaturated hydrocarbon chain with one or more double bonds or benzene rings, and polyether segment compound;
the first functional group comprises at least one selected from the group consisting of methyl, phenyl, sulfonic acid, carboxyl, nitroso, cyano, hydroxyl, amide, phenolic hydroxyl, sulfhydryl, amino, aldehyde, carbonyl, alkenyl, alkynyl, ether bond and thioether bond.

11. The quantum dot composition according to claim 10, wherein,
the second connection group comprises C1-C30 linear alkyl and unsaturated hydrocarbon chain with one or more double bonds or benzene rings;
the second functional group comprises at least one selected from the group consisting of sulfonic acid, carboxyl, nitroso, cyano, hydroxyl, amide, phenolic hydroxyl, sulfhydryl, amino, methyl, aldehyde, alkyl, carbonyl, alkenyl, alkynyl, ether bond and thioether bond.

12. The quantum dot composition according to claim 11, wherein,
the second functional group is at least one selected from the group consisting of sulfonic acid, carboxyl, nitroso, cyano, hydroxyl, amide, phenolic hydroxyl, sulfhydryl and amino, and the first functional group is at least one selected from the group consisting of methyl, aldehyde, carbonyl, alkenyl, alkynyl, ether bond and thioether bond; or
the second functional group is at least one selected from the group consisting of methyl, aldehyde, alkyl, carbonyl, alkenyl, alkynyl, ether bond and thioether bond, and the first functional group is at least one selected from the group consisting of phenyl, sulfonic acid, carboxyl, nitroso, cyano, hydroxyl, amide, phenolic hydroxyl, sulfhydryl and amino.

13. The quantum dot composition according to claim 3, further comprising a solvent, wherein the solvent is a weakly polar solvent or a nonpolar solvent, the first functional group is a weakly polar group or a nonpolar group, and the second functional group corresponding to the first functional group is a strongly polar group, and a dielectric constant of the weakly polar solvent or the nonpolar solvent is less than 3.6.

14. The quantum dot composition according to claim 13, wherein the first quantum dot ligand is 1-octanethiol or oleic acid, the photosensitizer is 2,3,4,5-tetrafluoro-4-azidebenzoic acid or 3-benzoyl benzoic acid, and the solvent is the weakly polar solvent or nonpolar solvent.

15. The quantum dot composition according to claim 14, wherein,
the weakly polar solvent or nonpolar solvent comprises at least one selected from the group consisting of cyclohexane, petroleum ether, octane, trimethylpentane, carbon tetrachloride, trichlorotrifluoroethane, p-xylene, chlorobenzene, 0-dichlorobenzene, diethyl ether, diethoxyethane, tetrahydrofuran, hexane, pentane, toluene and chlorobenzene.

16. The quantum dot composition according to claim 3, further comprising a solvent, wherein the solvent is a strongly polar solvent, the first functional group is a strongly polar group, and the second functional group corresponding to the first functional group is a weakly polar group or a nonpolar group, and a dielectric constant of the strongly polar solvent is greater than or equal to 3.6.

17. The quantum dot composition according to claim 16, wherein the first quantum dot ligand is 6-mercaptohexanol, the photosensitizer is 2,3,4,5-tetrafluoro-4-azido octadecyl benzene, and the solvent is the strongly polar solvent.

18. The quantum dot composition according to claim 17, wherein the strongly polar solvent comprises at least one selected from the group consisting of methanol, ethanol, isopropanol, ethyl acetate, acetonitrile, acetone, acetic acid, pyridine, N,N-dimethylformamide and dimethyl sulfoxide.

19. A patterning method of a quantum dot film, comprising:
providing a substrate;
applying the quantum dot composition according to claim 1 on the substrate to form a quantum dot film;
shielding the quantum dot film with a mask plate, and irradiating a partial region of the quantum dot film with light to increase a molecular weight of the quantum dot ligand and change a polarity of the quantum dot ligand in the partial region;
developing the quantum dot film with a developer to obtain a patterned quantum dot film.

20-23. (canceled)

24. A quantum dot display device, comprising a quantum dot film prepared from the quantum dot composition according to claim 1.

25-26. (canceled)
